(19) United States
(12) Patent Application Publication
(10) Pub. No.: US 2026/0123241 A1
(43) Pub. Date: Apr. 30, 2026

(54) LIGHT EMITTING DISPLAY DEVICE

(71) Applicant: LG Display Co., Ltd., Seoul (KR)

(72) Inventor: Dongik Kim, Paju-si (KR)

(73) Assignee: LG Display Co., Ltd., Seoul (KR)

(21) Appl. No.: 19/004,113

(22) Filed: Dec. 27, 2024

(30) Foreign Application Priority Data
Dec. 29, 2023 (KR) 10-2023-0197493

(51) Int. Cl. H10K 59/80; H10K 59/12; H10K 59/122; H10K 59/131

(52) U.S. Cl. CPC H10K 59/873; H10K 59/1201; H10K 59/122; H10K 59/131; H10K 59/80521

(57) ABSTRACT

A light emitting display device can include a display area disposed in a middle portion of a substrate, a non-display area adjacent to the display area on the substrate, a boundary area disposed in the non-display area near the display area, a pattern electrode disposed in the boundary area and surrounding the display area, a trench along the pattern electrode, and an under-cut disposed at least one side of the pattern electrode along the trench.

### CROSS-REFERENCE TO RELATED APPLICATIONS

This application claims priority to Korean Patent Application No. 10-2023-0197493, filed in the Republic of Korea on Dec. 29, 2023, the entire contents of which are hereby expressly incorporated by reference into the present application.

### BACKGROUND

### Field

The present disclosure relates to a light emitting display. In particular, without limitation, the present disclosure relates to a light emitting display device having a structure for reducing or preventing hydrogen particle and moisture from intruding into the display device.

### Discussion of the Related Art

Among display device, light emitting display devices as a self-emitting type has excellent viewing angles and contrast ratio, may not require an additional backlight, can be lightweight and thin, and has advantages in low power consumption. In particular, among the light emitting display devices, organic light emitting display devices can have the advantages of driving at low direct current voltages, fast response speeds, and low manufacturing costs.

The light emitting display device can include a plurality of light emitting diodes. The light emitting diode can include an anode electrode, an emission layer disposed on the anode electrode, and a cathode electrode disposed on the emission layer. The light emitting display device can display images by electrically controlling the amount of light generated from the emission layer of the light emitting diode.

The emission layer included in the light emitting display device, as an organic material, can be vulnerable to moisture. Therefore, the light emitting display device can include an encapsulation layer to prevent moisture or hydrogen particles from penetrating from the outside. However, it can be challenging to sufficiently prevent moisture or hydrogen particles from penetrating from the outside by using the encapsulation layer alone. As such, a light emitting display device can need a structure that can prevent moisture from penetrating from the outside and, at the same time, can suppress diffusion of moisture and hydrogen particles through the internal organic layer.

### SUMMARY OF THE DISCLOSURE

One purpose of the present disclosure, as for solving the limitations described above, is to provide a light emitting display having a structure in which moisture or hydrogen particles can be prevented from penetrating from the outside or diffusing into the internal element through organic materials.

In addition, some aspects of the present disclosure have technical tasks of providing a structure in which the organic layer that can extend from the non-display area to the display area can be disconnected by using a metal layer surrounding the display area where pixels are arranged.

Moreover, in some aspects of the present disclosure, the metal layer surrounding the display area where the pixels are arranged can be used as a shorting bar to prevent static electricity during the manufacturing process, and the connectivity of the organic layer extending from the non-display area to the display area can be cut off after the product is completed.

In order to accomplish the above-mentioned objects, a light emitting display according to aspects of the present disclosure comprises a display area disposed in a middle portion of a substrate; a non-display area surrounding the display area on the substrate; a boundary area disposed in the non-display area near the display area; a pattern electrode disposed in the boundary area and surrounding the display area; a trench along the pattern electrode; and an under-cut disposed at least one side of the pattern electrode along the trench.

In one aspect of the present disclosure, the display device further comprises an insulating layer deposited on the pattern electrode. The trench is an area where the insulating layer is removed along a first side of the pattern electrode. The under-cut is a space formed by the first side of the pattern electrode being eroded into a lower inside of the insulating layer.

In one aspect of the present disclosure, the display device further comprises an emission layer on the insulating layer; and a cathode electrode on the emission layer. The emission layer is disconnected by the trench and the under-cut between the display area and the non-display area. The cathode electrode contacts the pattern electrode exposed by the under-cut, and fills inside of the trench.

In one aspect of the present disclosure, the display device further comprises an encapsulation layer on the cathode electrode. The encapsulation layer covers the trench.

In one aspect of the present disclosure, wherein the pattern electrode includes: a first side facing the display area; and a second side apart from the first side to the non-display area. The trench includes: a first trench along the first side; and a second trench along the second side. The under-cut includes: a first under-cut along the first side; and a second under-cut along the second side.

In one aspect of the present disclosure, the display device further comprises an insulating layer on the pattern electrode; an emission layer on the insulating layer; and a cathode electrode on the emission layer. The emission layer is disconnected at the first trench and the second trench. The cathode electrode contacts the first side of the first pattern electrode exposed by the first under-cut, and the second side of the first pattern electrode exposed by the second under-cut, and fills inside of the trench.

In one aspect of the present disclosure, the pattern electrode includes: a first pattern electrode near the display area; and a second pattern electrode apart from the first pattern electrode to the non-display area. The trench includes: a first trench disposed between the first pattern electrode and the display area; a second trench disposed between the second pattern electrode and the non-display area; and a third trench disposed between the first pattern electrode and the second pattern electrode. The under-cut includes: a first under-cut disposed at the first pattern electrode along the first trench; a second under-cut disposed at the second pattern electrode along the second trench; a third under-cut disposed at the first pattern electrode in the third trench; and a fourth under-cut disposed at the second pattern electrode in the third trench.

In one aspect of the present disclosure, the pattern electrode further comprises an insulating layer disposed on the first pattern electrode and the second pattern electrode; an emission layer on the insulating layer; and a cathode electrode on the emission layer. The emission layer is disconnected at the first trench, the second trench and the third trench. The cathode electrode contacts the first pattern electrode exposed by the first under-cut and the third under-cut, and the second pattern electrode exposed by the second under-cut and the fourth under-cut, and fills insides of the first trench, the second trench and the third trench.

In one aspect of the present disclosure, the pattern electrode further comprises a scan line disposed in the display area; a gate signal line disposed at out of the boundary area in the non-display area; and a link line overlapped with the pattern electrode in the boundary area, and connecting the scan line to the gate signal line.

In one aspect of the present disclosure, the trench is disposed between the pattern electrode and the scan line. The display device further comprises a scan line under-cut disposed at one side of the scan line facing the pattern electrode.

In one aspect of the present disclosure, the display device further comprises a gate driving area near to the boundary area and far from the display area; a scan line disposed in the non-display area; a gate signal line disposed in the gate driving area; and a link line overlapped with the pattern electrode in the boundary area, and connecting the scan line to the gate signal line.

In one aspect of the present disclosure, the display device further comprises an insulating layer on the pattern electrode; an emission layer on the insulating layer; and a cathode electrode on the emission layer. The trench includes a first trench formed by removing the insulating layer between the pattern electrode and the scan line. The under-cut includes a first under-cut formed by one end of the pattern electrode being eroded under the insulating layer in the first trench. The emission layer is disconnected by the first trench and the first under-cut. The cathode electrode contacts the pattern electrode exposed by the first under-cut, and fills inside of the first trench.

In one aspect of the present disclosure, the display device further comprises a scan line under-cut formed by one end of the scan line being eroded under the insulating layer in the first trench; and a bank disposed on the insulating layer, and covering the scan line under-cut.

In one aspect of the present disclosure, the display device further comprises an insulating layer covering the pattern electrode; an emission layer on the insulating layer; and a cathode electrode on the emission layer. The trench includes a second trench formed by removing the insulating layer between the pattern electrode and the gate signal line. The under-cut includes a second under-cut formed by another end of the pattern electrode being eroded under the insulating layer in the second trench. The emission layer is disconnected by the second trench and the second under-cut. The cathode electrode contacts the pattern electrode exposed from the second under-cut, and fills inside of the second trench.

In one aspect of the present disclosure, the display device further comprises a gate signal line under-cut formed by end of the gate signal line being eroded under the insulating layer in the second trench; and a bank disposed on the insulating layer, and covering the gate signal line under-cut.

The light emitting display according to the present disclosure can have a pattern electrode layer made of a metal material disposed adjacent to the display area in a non-display area surrounding the display area. The display device can have a structure that forms a trench and an undercut along the boundary line of the pattern electrode layer to disconnect the connectivity of the organic emission layer deposited from the non-display area to the display area. Therefore, even though moisture or hydrogen particles penetrate from the outside environment, diffusion into the display area along the organic emission layer can be blocked. As a result, the elements of the display device can be protected for a long time, and the service life of the display device can be ensured.

In addition, during the manufacturing process, various lines formed in the display area can be connected to the pattern electrode layer and used as an element to discharge the static electricity generated during the manufacturing process to outside. By forming a trench and an undercut at the pattern electrode layer just before depositing the organic emission layer, the pattern electrode layer and various lines can be separated and the lines can have their original functions. The pattern electrode layer separated from the lines can be used as a ground line.

In addition to the effects and advantages described in the present disclosure mentioned above, other features and advantages of the present disclosure are described below, and from such description, it will be clearly understood by those skilled in the art to which the present disclosure belongs.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating an overall schematic structure of a light emitting display according to an embodiment of the present disclosure.

FIG. 2 is an equivalent circuit diagram illustrating a structure of one pixel included in the light emitting display according to an aspect of the present disclosure.

FIG. 3 is an enlarged plan view of dotted box ‘X’ in FIG. 1, illustrating a structure of a light emitting display device according to a first example aspect of the present disclosure.

FIG. 4 is an enlarged cross-sectional view, along the cutting line I-I′ in FIG. 3, illustrating a structure of a light emitting display device according to the first example aspect of the present disclosure.

FIG. 5 is an enlarged plan view of dotted box ‘X’ in FIG. 1, illustrating a structure of a light emitting display device according to a second example aspect of the present disclosure.

FIG. 6 is an enlarged cross-sectional view, along the cutting line II-II′ in FIG. 5, illustrating a structure of a light emitting display device according to the second example aspect of the present disclosure.

FIG. 7 is an enlarged plan view of dotted box ‘X’ in FIG. 1, illustrating a structure of a light emitting display device according to a third example aspect of the present disclosure.

FIG. 8 is an enlarged cross-sectional view, along the cutting line III-III′ in FIG. 7, illustrating a structure of a light emitting display device according to the third example aspect of the present disclosure.

FIG. 9 is an enlarged plan view of dotted box ‘X’ in FIG. 1, illustrating a structure of a light emitting display device according to a fourth example aspect of the present disclosure.

FIG. 10 is an enlarged cross-sectional view, along the cutting line IV-IV′ in FIG. 9, illustrating a structure of a light emitting display device according to the fourth example aspect of the present disclosure.

FIGS. 11A to 11C are enlarged plane views illustrating a method for manufacturing a light emitting display device according to a fifth example aspect of the present disclosure.

FIGS. 12A to 12F are enlarged cross-sectional views, along the cutting line V-V′ in FIG. 11A to 11C, illustrating a method for manufacturing the light emitting display device according to the fifth example aspect of the present disclosure.

FIGS. 13A and 13B are enlarged plane views illustrating a method for manufacturing a light emitting display device according to a sixth example aspect of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure may, however, be embodied in different forms and should not be construed as limited to the embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the disclosure unless otherwise specified. In the following description, where the detailed description of the relevant known function or configuration can unnecessarily obscure an important point of the present disclosure, a detailed description of such known function of configuration can be omitted.

Reference will now be made in detail to the example embodiments of the present disclosure, examples of which are illustrated in the accompanying drawings. Wherever possible, the same reference numbers will be used throughout the drawings to refer to the same or like parts. In the disclosure, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the disclosure should be understood as follows.

In the present disclosure, where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed there-between. Further, if a first element is described as positioned “on” a second element, it does not necessarily mean that the first element is positioned above the second element in the figure. The upper part and the lower part of an object concerned can be changed depending on the orientation of the object. Consequently, where a first element is described as positioned “on” a second element, the first element can be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

It will be understood that, although the terms “first,” “second,” and the like can be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing the components of the present disclosure, terms such as ‘first’, ‘second’, ‘A’, ‘B’, ‘(a)’ and ‘(b)’ can be used. These terms are only used to distinguish the components from other components, and the nature, sequence, order or number of the corresponding component is not limited by the term. Where an element is described as being “linked”, “coupled,” or “connected” to another element, that element can be directly or indirectly connected to that other element unless otherwise specified. It is to be understood that additional element or elements can be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship. Further, the term “can” fully encompasses all the meanings and coverages of the term “may.”

Hereinafter, examples of a display apparatus according to the present disclosure will be described in detail with reference to the attached drawings. All the components of each display apparatus according to all embodiments of the present disclosure are operatively coupled and configured. Wherever possible, the same reference numbers will be used throughout the drawings to refer to the same or like parts. Since a scale of each of elements shown in the accompanying drawings can be different from an actual scale for convenience of description, the present disclosure is not limited to the scale shown in the drawings.

Hereinafter, referring to the attached figures, various example aspects of the present disclosure will be explained. The scales of the elements shown in the drawings have different scales from actual ones for convenience of explanation, so they are not limited to the scales shown in the drawings.

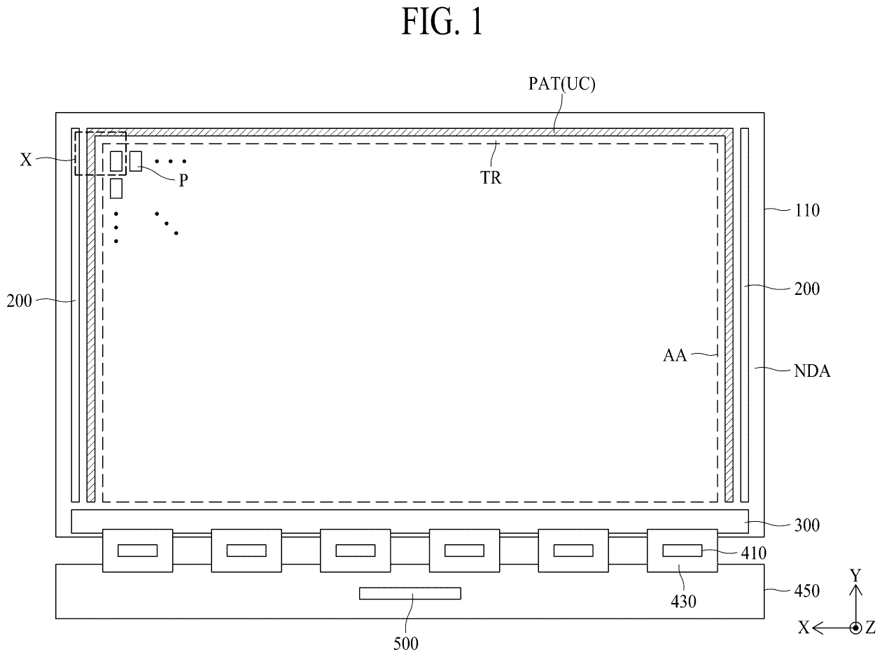

FIG. 1 is a plan view illustrating an overall schematic structure of a light emitting display according to an embodiment of the present disclosure. In FIG. 1, an X-axis refers to the direction parallel to the scan line, a Y-axis refers to the direction of the data line, and a Z-axis refers to the height direction of the display device.

Referring to FIG. 1, a light emitting display comprises a substrate 110, a gate (or scan) driver 200, a pad portion 300, a source driving IC (Integrated Circuit) 410, a flexible circuit film 430, a circuit board 450, and a timing controller 500.

The substrate 110 can include an electrical insulating material or a semiconductor material, without being limited thereto. As an example, the substrate 110 may include a rigid material or a flexible material. The substrate 110 can be made of a glass, a metal or a plastic, but it is not limited thereto. When the electroluminescence display is a flexible display, the substrate 110 can be made of the flexible material such as plastic. For example, the substrate 110 can include a transparent polyimide material.

The substrate 110 can include a display area AA (active area) and a non-display area NDA (non-active area). The display area AA, which is an area for representing the video images, can be defined as the majority area (e.g., majority middle area) of the substrate 110, but it is not limited thereto. The non-display area NDA can surround the display area AA entirely or only in part(s). In the display area AA, a plurality of pixels P can be arrayed in a matrix manner. Further, a plurality of scan lines SL (or gate lines) and a plurality of data lines DL can be disposed as crossing each other. Each of pixels P can be disposed at the area formed by crossing of the scan line SL and the data line DL.

Here, each pixel P can have any one color of red, green and blue, or any one of red, green, blue and white, without being limited thereto. As an example, a pixel having a color (e.g., cyan, magenta, or yellow, etc.) other than red, green, blue and white may be alternatively or additionally included. A red pixel, a green pixel and a blue pixel can be gathered together, or a red pixel, a green pixel, a blue pixel and a white pixel can be gathered together to form one unit pixel, without being limited thereto. For example, each pixel representing each color can be named a ‘sub-pixel’ and it can be explained that these ‘sub-pixels’ form one ‘pixel’. For another example, each pixel representing each color can be named ‘pixels P’, and it can be explained that three or four of these ‘pixels P’ are gathered together to form one ‘unit pixel’. Hereinafter, the latter method can be used for description.

The non-display area NDA, which is an area not representing the video images, can be defined at the circumference areas of the substrate 110 surrounding all or some of the display area AA. The display device according to the present disclosure can have the display area AA disposed at the middle portion of a substrate 110 having a rectangular plate shape, and the non-display area NDA surrounding four sides of the display area AA. In the non-display area NDA, the gate driver 200 and the pad portion 300 can be formed or disposed. Embodiments are not limited thereto. As an example, the display area AA may be disposed at a position biased from the middle portion of a substrate 110. As an example, the substrate 110 may have various shapes such as a polygonal shape, an oval shape, a circular shape, and the non-display area NDA may surround all or some sides of the display area AA. As an example, the gate driver 200 may be not formed or disposed in the non-display area NDA.

A pattern electrode PAT can be disposed in the non-display area NDA. As an example, the pattern electrode PAT may be disposed in the non-display area NDA near to the display area AA, without being limited thereto. As an example, the pattern electrode PAT may be disposed in the non-display area NDA, such that the pattern electrode PAT is closer to the display area AA than to the circumference of the non-display area NDA, without being limited thereto. A trench TR can be disposed between the pattern electrode PAT and the display area AA. The pattern electrode PAT can include an under-cut UC. The detailed structure of the pattern electrode PAT, under-cut UC and trench TR will be described in the following aspects.

The gate driver 200 can supply the scan (or gate) signals to the scan lines according to the gate control signal received from the timing controller 500 through the pad portion 300. The gate driver 200 can be formed at the non-display area NDA disposed at a circumferential area of the display area AA on the substrate 110, as a GIP (Gate driver In Panel) type. GIP type means that the gate driver 200 is directly formed on the substrate 110. For example, the gate driver 200 can include a shift register. The GIP type refers to a structure in which transistors included in the shift register of the gate driver 200 are formed directly on the substrate 100. Embodiments are not limited thereto. As an example, the gate driver 200 may be connected to the non-display area NDA (e.g., a bonding pad) using a tape automated bonding (TAB) method, or may be connected to the non-display area NDA (e.g., a bonding pad) using a chip-on-glass (COG) or chip-on-panel (COP) method, or may be implemented using a chip-on-film (COF) method and connected to the non-display area NDA, without being limited thereto.

The data pad portion 300 can be disposed in the non-display area NDA disposed at one edge, opposite edge or more edges of the display area AA of the substrate 100. The pad portion 300 includes data pads connected to each of the data lines, driving current pads connected to the driving current line, a high-potential pad receiving a high-level voltage, and a low-potential pad receiving a low-level voltage, without being limited thereto.

The source driving IC 410 can receive the digital video data and the source control signal from the timing controller 500. The source driving IC 410 can convert the digital video data into the analog data voltages according to the source control signal and then supply that to the data lines. When the source driving IC 410 is made as a chip type, it can be installed on the flexible circuit film 430 as a COF (Chip On Film) or COP (Chip On Plastic) type, without being limited thereto.

The flexible circuit film 430 can include a plurality of first link lines connecting the pad portion 300 to the source driving IC 410, and a plurality of second link lines connecting the pad portion 300 to the circuit board 450, without being limited thereto. The flexible circuit film 430 can be attached on the pad portion 300 using an anisotropic conducting film, so that the pad portion 300 can be connected to the first link lines of the flexible circuit film 430, without being limited thereto. As an example, the pad portion 300 may be connected to the circuit board 450 via the source driving IC 410. In this case, the second link lines may be omitted, without being limited thereto.

The circuit board 450 can be attached to the flexible circuit film 430. The circuit board 450 can include a plurality of circuits implemented as the driving chips. For example, the circuit board 450 can be a printed circuit board or a flexible printed circuit board.

The timing controller 500 can receive the digital video data and the timing signal from an external system board through the line cables of the circuit board 450. The timing controller 500 can generate a gate control signal for controlling the operation timing of the gate driver 200 and a source control signal for controlling the source driving IC 410, based on the timing signal. The timing controller 500 can supply the gate control signal to the gate driver 200 and supply the source control signal to the source driving IC 410. Depending on the product types, the timing controller 500 can be formed as one chip with the source driving IC 410 and mounted on the substrate 110, without being limited thereto.

### First Example Aspect

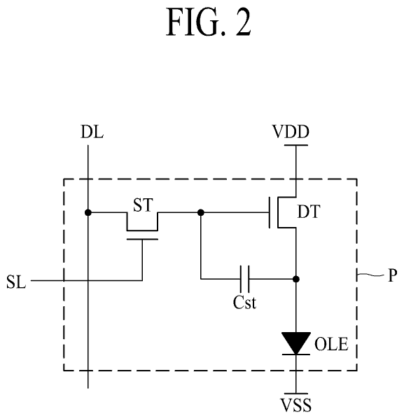

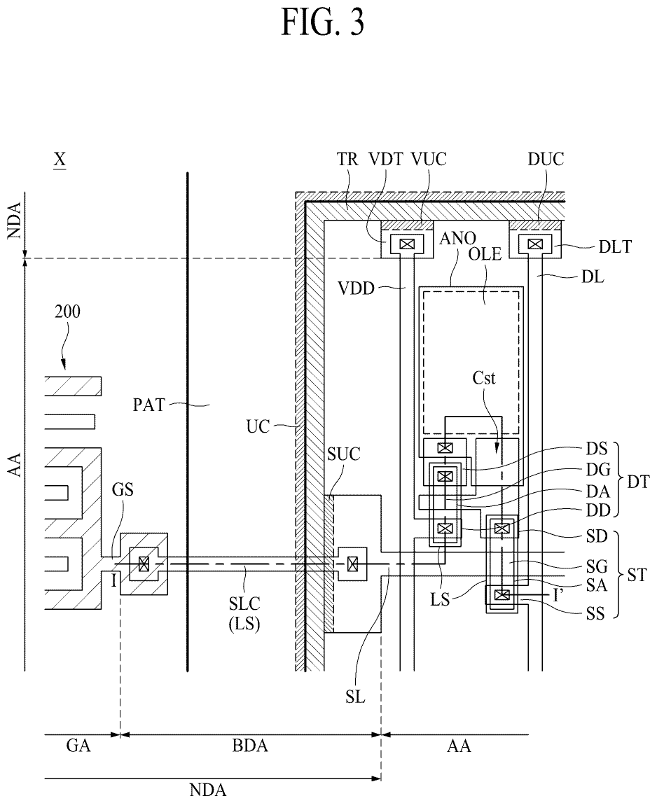

Hereinafter, further referring to FIGS. 2 to 4, a structure of a light emitting display device according to a first example aspect of the present disclosure will be described. FIG. 2 is an equivalent circuit diagram illustrating a structure of one pixel included in the light emitting display according to an aspect of the present disclosure. FIG. 3 is an enlarged plan view of dotted box ‘X’ in FIG. 1, illustrating a structure of a light emitting display device according to the first example aspect of the present disclosure.

Referring to FIG. 2 and FIG. 3, a light emitting display device according to the present disclosure includes a plurality of pixels P which can be defined by a scan line SL, a data line DL and a driving current line VDD. One pixel P of the light emitting display can include a switching thin film transistor ST, a driving thin film transistor DT, a light emitting diode OLE and a storage capacitance (or capacitor) Cst. The driving current line VDD can be supplied with a high-level voltage for driving the light emitting diode OLE. Embodiments are not limited thereto. As an example, the circuit structure of one pixel P could be variously changed. As an example, one or more transistors and/or one or more capacitors could be further included.

A switching thin film transistor ST and a driving thin film transistor DT can be formed on a substrate SUB. For example, the switching thin film transistor ST can be disposed at the portion where the scan line SL and the data line DL is crossing. The switching thin film transistor ST can include a gate electrode SG, a semiconductor layer SA, a source electrode SS and a drain electrode SD. The gate electrode SG of the switching thin film transistor ST can be a part of the scan line SL or branched from the scan line SL. The semiconductor layer SA can be disposed as crossing the gate electrode SG. The overlapped portions of the semiconductor layer SA with the gate electrode SG can be defined as the channel area. The source electrode SS can be a part of the data line DL or be connected to or branched from the data line DL and the drain electrode SD can be connected to the driving thin film transistor DT. One side of the semiconductor layer SA is connected to the source electrode SS, and the other side of the semiconductor layer SA is connected to the drain electrode SD. By supplying the data signal to the driving thin film transistor DT, the switching thin film transistor ST can play a role of selecting a pixel which would be driven.

The driving thin film transistor DT can play a role of driving the light diode OLE of the selected pixel by the switching thin film transistor ST. The driving thin film transistor DT can include a gate electrode DG, a semiconductor layer DA, a source electrode DS and a drain electrode DD. The gate electrode DG of the driving thin film transistor DT can be connected to the drain electrode SD of the switching thin film transistor ST. For example, the gate electrode DG of the driving thin film transistor DT can be connected to or extended from the drain electrode SD of the switching thin film transistor ST. In the driving thin film transistor DT, the drain electrode DD is a part of the driving current line VDD, or is connected to or branched from the driving current line VDD, and the source electrode DS is connected to a pixel electrode ANO of the light emitting diode (or light emitting element) OLE. The semiconductor layer DA can be disposed as crossing the gate electrode DG. The overlapped area of the semiconductor layer DA with the gate electrode DG can be defined as a channel area. The source electrode DS is connected to one side of the semiconductor layer DA, and the drain electrode DD is connected to the other side of the semiconductor layer DA. A storage capacitance Cst can be disposed between a part of the gate electrode DG or an electrode connected to or branched from the gate electrode DG of the driving thin film transistor DT and a part of or an electrode connected to or branched from the anode electrode ANO of the light emitting diode OLE.

The driving thin film transistor DT can be disposed between the driving current line VDD and the light emitting diode OLE. The driving thin film transistor DT can control the amount of currents flowing from the driving current line VDD to the light emitting diode OLE in accordance with the voltage difference between the gate electrode DG and the source electrode DS.

The light emitting diode OLE can include an anode electrode ANO, an emission layer and a cathode electrode. The light emitting diode OLE can display an image by emitting light according to a current controlled by the driving thin film transistor DT. For example, the light emitting diode OLE can generate light to represent the images in accordance with the current controlled by the driving thin film transistor DT. The anode electrode ANO of the light emitting diode OLE is connected to the source electrode DS of the driving thin film transistor DT, and the cathode electrode CAT is connected to the low-power line VSS to which a low-level voltage is supplied. Accordingly, the light emitting diode OLE is driving by the current flowing from the driving current line VDD to the low-power line VSS in accordance with the operation of the driving thin film transistor DT.

A plurality of pixels P can be disposed on the substrate 110. For example, a red pixel, a green pixel and a blue pixel can be consecutively arranged in a line. As an example, a red pixel, a green pixel and a blue pixel may be consecutively arranged in the horizontal direction. The red pixel, the green pixel and the blue pixel can form one unit pixel. For another example, a red pixel, a green pixel, a white pixel and a blue pixel can be consecutively arranged in the horizontal direction. The red pixel, the green pixel, the white pixel and the blue pixel can form one unit pixel. Embodiments are not limited thereto. As an example, pixels forming one unit pixel may be arranged in various ways. As an example, pixels forming one unit pixel may be arranged in two or more lines in the horizontal direction or the vertical direction, without being limited thereto.

In addition, the light emitting display device according to the present disclosure can include a display area AA and a non-display area NDA. The non-display area NDA can include a gate driving area GA and a boundary area BDA. As an example, the boundary area BDA may be disposed between the gate driving area GA and the display area AA, without being limited thereto. The gate driving area GA can include the gate driver 200. The gate driver 200 can include thin film transistor supplying the scan signal via the scan line SL to the switching thin film transistor ST disposed in the display area AA.

The boundary area BDA can include a pattern electrode PAT and a link line SLC. The pattern electrode PAT can have a bent segment shape having a predetermined width surrounding the display area AA, without being limited thereto. The link line SLC can be the line connecting the gate signal line GS outputting the gate signal from the gate driver 200 to the scan line SL. The link line SLC can be formed on a layer different from the layer for the pattern electrode PAT in order not to be connected to the pattern electrode PAT.

Among the two parallel sides configuring the width of the pattern electrode PAT, the under-cut UC can be formed at the side adjacent to the display area AA. Further, the trench TR can be formed between the under-cut UC and the display area AA. The under-cut UC can be an element made by the trench TR, without being limited thereto. For example, the trench TR can be formed by removing the insulating layer covering the patten electrode PAT along a side of the pattern electrode PAT, the side being adjacent to the display area AA. After that, the sidewall of the pattern electrode PAT exposed from the trench TR can be over-etched to form the under-cut UC.

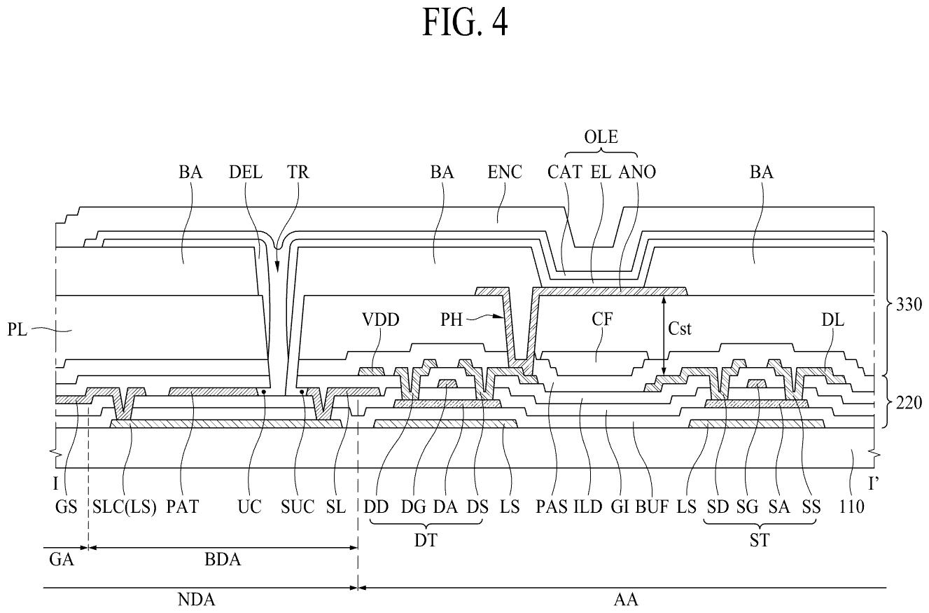

Further referring to FIG. 4, the cross-sectional structure of the light emitting display according to the first example aspect will be explained. FIG. 4 is an enlarged cross-sectional view, along the cutting line I-I′ in FIG. 3, illustrating a structure of a light emitting display device according to the first example aspect of the present disclosure. The light emitting display device, can include a substrate 110, a driving element layer 220, a light emitting element layer 330, and an encapsulation layer ENC. The driving element layer 220 can include a plurality of layers formed on the substrate 110. The driving element layer 220 can include a switching thin film transistor ST and a driving thin film transistor DT.

In detail, a light shielding layer LS can be formed on the substrate 110. The light shielding layer LS can have an island shape overlapping with the semiconductor layer SA of the switching thin film transistor ST and the semiconductor layer DA of the driving thin film transistor DT, respectively, without being limited thereto. As an example, the light shielding layer LS may have a plate shape overlapping with both the semiconductor layer SA of the switching thin film transistor ST and the semiconductor layer DA of the driving thin film transistor DT. As an example, the light shielding layer LS may be omitted depending on the design. In addition, a link line SLC made of the same material as the light shielding layer LS can be disposed in the boundary area BDA. The link line SLC can be a line for connecting the gate signal line GS to the scan line SL. Embodiments are not limited thereto. As an example, the link line SLC may be disposed on the same layer as the light shielding layer LS, or may be disposed on a different layer. As an example, the link line SLC may be made of a material different from the light shielding layer LS.

A buffer layer BUF can be deposited on the light shielding layer LS and the link line SLC as covering the entire surface of the substrate 110. The semiconductor layer SA of the switching thin film transistor ST and the semiconductor layer DA of the driving thin film transistor DT can be formed on the buffer layer BUF, or may be formed on different layers. The channel areas of the semiconductor layers SA and DA can be disposed as overlapping with the light shielding layer LS.

A gate insulating layer GI can be deposited on the substrate 110 having the semiconductor layers SA and DA. A gate electrode SG overlapping with the semiconductor layer SA of the switching thin film transistor ST and a gate electrode DG overlapping with the semiconductor layer DA of the driving thin film transistor DT are formed on the gate insulating layer GI, or may be formed on different layers. In addition, the pattern electrode PAT, the scan line SL and the gate signal line GS are formed on the gate insulating layer GI, or may be formed on different layers. The pattern electrode PAT can be spaced from the scan line SL and the gate signal line GS with certain distance, and can be overlapped with the link line SLC. The scan line SL can be disposed in the display area AA, and the gate signal line GS can be disposed in the non-display area NDA. The scan line SL can be connected to one end of the link line SLC, and the gate signal line GS can be connected to the other end of the link line SLC.

An intermediate insulating layer ILD can be deposited on the substrate 110 having the gate electrodes SG and DG. The intermediate insulating layer ILD can be made of an inorganic material such as silicon oxide or silicon nitride, without being limited thereto.

The data line DL, a source electrode SS and a drain electrode SD of the switching thin film transistor ST, and a source electrode DS and a drain electrode DD of the driving thin film transistor DT can be formed on the intermediate insulating layer ILD, or may be formed on different layers. The source electrode SS of the switching thin film transistor ST can be connected to one side of the semiconductor layer SA of the switching thin film transistor ST, and the drain electrode SD can be connected to another side of the semiconductor layer SA. Like this, the source electrode DS of the driving thin film transistor DT can be connected to one side of the semiconductor layer DA of the driving thin film transistor DT, and the drain electrode DD can be connected to another side of the semiconductor layer DA.

A passivation layer PAS can be deposited on the substrate 110 having the switching thin film transistor ST and the driving thin film transistor DT. The passivation layer PAS can be made of an inorganic material such as silicon oxide and/or silicon nitride, without being limited thereto.

A color filter CF can be formed on the passivation layer PAS. The color filter CF can have a size larger (e.g., slightly larger) than the light emitting diode OLE formed later, and to cover the light emitting diode OLE completely. The color filter CF can be arranged in a structure in which any one of a red color filter, a green color filter and a blue color filter can be assigned to one pixel P. The present disclosure relates to the bottom emission type light emitting display device. Therefore, the color filter CF can be disposed under the light emitting diode OLE. The elements from the light shielding layer LS to the color filter CF can be named as the driving element layer 220.

A light emitting element layer 330 can be formed on the driving element layer 220. The light emitting element layer 330 can include a planarization layer PL and a light emitting diode OLE. The planarization layer PL can be a thin film used to flatten the uneven surface condition of the substrate 110 on which the thin film transistors ST and DT are formed. In order to equalize the height difference due to the uneven surface condition, the planarization layer PL can be formed of an organic material, without being limited thereto. A pixel contact hole PH can be formed at the passivation layer PAS and the planarization layer PL for exposing a portion of the source electrode DA of the driving thin film transistor DT.

An anode electrode (or pixel electrode) ANO can be formed on the upper surface of the planarization layer PL. The anode electrode ANO can be connected to the source electrode DS of the driving thin film transistor DT through the pixel contact hole PH. The anode electrode ANO can have different elements and structure depending on the type of light emitting diode OLE. For example, in the case of a bottom emission type that provides light in the direction of the substrate 110, the anode electrode ANO can be made of a transparent conductive material. For another example, in case of top emission type that provides light in an upward direction opposite to the substrate 110, the anode electrode ANO can be made of a metal material having excellent light reflectance, without being limited thereto. As an example, even in case of top emission type, the anode electrode ANO may be made of a conductive material (e.g., a transparent, semitransparent or opaque conductive material) other than metal material. The present disclosure relates to the bottom emission type display device. Therefore, the anode electrode ANO is made of a transparent conductive material such as indium tin oxide (ITO) or indium zinc oxide (IZO), without being limited thereto.

When patterning the anode electrode ANO, a trench TR can be formed between the pattern electrode PAT and the scan line SL. Before forming the trench TR, the pattern electrode PAT and the scan line SL can be one-body metal pattern layer. The trench TR can be formed by etching the intermediate insulating layer ILD, the passivation layer PAS and the planarization layer PL which cover the one-body metal pattern layer of the pattern electrode PAT and the scan line SL. After the trench TR is formed and then the one-body metal pattern layer of the pattern electrode PAT and the scan line SL is exposed, the one-body metal pattern layer can be further etched to separate the pattern electrode PAT from the scan line SL. After that, using over-etching process, the end lines of the pattern electrode PAT and the scan line SL can be formed to be further etched into the lower part of the intermediate insulating layer ILD. As a result, under the intermediate insulating layer ILD, an under-cut UC can be formed at the end line of the pattern electrode PAT, and a scan line under-cut SUC can be formed at the end line of the scan line SL. Embodiments are not limited thereto. As an example, the trench TR, the pattern electrode PAT and the scan line SL may be formed in various ways. As an example, the pattern electrode PAT and the scan line SL may be separately formed. As an example, the pattern electrode PAT and the scan line SL may be formed of different materials and even formed on different layers during separate processes, without being limited thereto.

A bank BA can be formed on the substrate 110 having the anode electrode ANO and the trench TR. The bank BA can be an insulating layer made of an organic material or an inorganic material. Here, it is explained in the case where the bank BA is made of an inorganic material. The bank BA can cover circumferences of the anode electrode ANO to expose a portion (e.g., most middle portion) of the anode electrode ANO. The portion of the anode electrode ANO exposed from the bank BA can be defined as an emission area, and the covered area by the bank BA can be defined as a non-emission area.

The bank BA can be formed so that the under-cut UC formed at the end line of the pattern electrode PAT can be exposed in the portion where the trench TR is formed. For example, the end of the bank BA can be disposed as covering some of the upper surface of the planarization layer PL. On the contrary, the bank BA can be disposed as completely covering the scan line under-cut SUC formed at the end line of the scan line SL.

An emission layer EL can be deposited on the anode electrode ANO and the bank BA. The emission layer EL can be deposited over the entire display area AA of the substrate 110 to cover the anode electrode ANO and the bank BA. For example, the emission layer EL can include two or more emission portions for generating white light, without being limited thereto. For an example, the emission layer EL can include a first emission portion generating a first color light and a second emission portion generating a second color light which are vertically stacked for generating white light by mixing the first color light and the second color light, without being limited thereto.

For another example, the emission layer EL can include any one emission portion of a blue emission portion, a green emission portion and a red emission portion for generating one color light corresponding to the color allocated in the pixel, without being limited thereto. Further, the light emitting diode OLE can include functional layers to improve the luminous efficiency and/or lifespan of the emission layer EL, without being limited thereto.

The emission layer EL can be deposited so as covering entire display area AA and some of the non-display area NDA. The emission layer EL can be deposited as one common layer covering entire display area AA. However, the connectivity of the emission layer EL can be disconnected at the area where the trench TR is formed, due to the structure of the trench TR and the under-cut UC. Since the emission layer EL is made of an organic material, the emission layer EL can be deposited only to a certain depth at the side walls of the trench TR, and can be not deposited at the lower part of the trench TR and the inside the under-cut UC. For example, the connectivity of the emission layer EL can be interrupted or disconnected by the trench TR and the under-cut UC. Therefore, the portion of the emission layer EL disposed in the non-display area NDA can be named as a dummy emission layer DEL, and the portion of the emission layer EL disposed in the display area AA can be named as the emission layer EL.

A cathode electrode (or common electrode) CAT can be deposited on entire surface of the substrate 110 having the emission layer EL. The cathode electrode CAT can be deposited as being surface contacting with the emission layer EL. The cathode electrode CAT can be formed across the entire substrate 110 to be commonly connected to the emission layer EL formed in all pixels. In case of the bottom emission type, the cathode electrode CAT can be made of a metal material having excellent light reflectance with a thickness of 2,000 Å or more. Here, the metal material can be at least one of aluminum (Al), magnesium (Mg), calcium (Ca), silver (Ag) and alloy of them (i.e., aluminum-magnesium (AlMg)). Embodiments are not limited thereto. As an example, the cathode electrode CAT may be made of a conductive material other than metal materials. As an example, the cathode electrode CAT may be formed to have a thickness of less than 2,000 Å. In the case of top emission type, the cathode electrode CAT can be made of a transparent conductive material. The present disclosure relates to the bottom emission type. By the stacking structure of the anode electrode ANO, the emission layer EL and the cathode electrode CAT, a light emitting diode OLE can be formed in each pixel P.

The cathode electrode CAT can be formed as covering whole of the emission layer EL. The cathode electrode CAT can be a common layer covering entire display area AA and some of the non-display area NDA. At the area where the trench TR is formed, the cathode electrode CAT can be deposited to completely fill the inside of the trench TR, due to the deposition characteristics of the inorganic metal material. Therefore, the cathode electrode CAT can be deposited to cover the entire display area AA and some of the non-display area NDA, and can be one connected metal layer extending from the display area AA to the non-display area NDA. As an example, the cathode electrode CAT may cover at least a portion of the emission layer DEL on the bank BA in the non-display area NDA. As an example, the cathode electrode CAT may cover an end of the emission layer DEL on the bank BA in the non-display area NDA. Alternatively, the cathode electrode CAT may cover a portion of the emission layer DEL on the bank BA in the non-display area NDA while exposing the end of the emission layer DEL.

Accordingly, the cathode electrode CAT can have a profile in which it is deposited to the inside of the under-cut UC and the bottom area of the trench TR, and fill the entire inside of the trench TR. As a result, the cathode electrode CAT can be physically connected to the pattern electrode PAT. On the contrary, since the scan line under-cut SUC formed at the end line of the scan line SL is covered by the bank BA, the scan line SL may not be connected to the cathode electrode CAT. In the plane view, in the case that the pattern electrode PAT is surrounding three sides of the display area AA, the pattern electrode PAT connected to the cathode electrode CAT can function as a ground line. Embodiments are not limited thereto. As an example, the pattern electrode PAT may surround one side, two sides, three sides or four sides of the display area AA. As an example, if the display area AA has a polygonal shape, the pattern electrode PAT may surround four or more sides of the display area AA, without being limited thereto.

Referring to FIG. 3, a driving terminal VDT connected to the driving current line VDD can be disposed at the upper end of the driving current line VDD. Further, a data terminal DLT connected to the data line DL can be disposed at the upper end of the data line DL. The driving terminal VDT and the data terminal DLT can be made of same material and at the same layer with the pattern electrode PAT, without being limited thereto. As an example, before forming the trench TR, the driving terminal VDT and the data terminal DLT can be connected to the pattern electrode PAT. As forming the trench TR and the under-cut UC, the driving terminal VDT and the data terminal DLT can be separated from the pattern electrode PAT. In addition, when forming the under-cut UC, by the over-etching process, a driving line under-cut VUC and a data line under-cut DUC having the same structure as the scan line under-cut SUC can be formed. Embodiments are not limited thereto. As an example, the driving terminal VDT and the data terminal DLT may be separately formed from the pattern electrode PAT. As an example, the driving terminal VDT and the data terminal DLT may be made of different materials and at different layers with the pattern electrode PAT.

An encapsulation layer ENC can be disposed on the light emitting element layer 220. The encapsulation layer ENC can have a single layered structure including an inorganic material or an organic material, or a multiple layered structure including a plurality of inorganic layers and/or a plurality of organic layers. For another example, the encapsulation layer ENC can have a structure in which inorganic layers and organic layers are alternately stacked. Here, for convenience of explanation, it is described as an encapsulation layer ENC including a single inorganic layer.

The encapsulation layer ENC can have a structure completely covering the cathode electrode CAT as extending from some of the non-display area NDA to entire display area AA. The encapsulation layer ENC can cover the cathode electrode CAT filling the inside of the trench TR. As an example, the encapsulation layer ENC may cover an end of the cathode electrode CAT as well as the end of the dummy emission layer DEL on the bank BA in the non-display area NDA.

The encapsulation layer ENC can reduce or prevent moisture or hydrogen particles from penetrating into the dummy emission layer DEL from the outside environment. However, at the outermost end of the encapsulation layer ENC shown in FIG. 4, for example at the interface between the encapsulation layer ENC and the planarization layer PL (or the bank BA), moisture or hydrogen particles can penetrate. Moisture or hydrogen particles penetrated through the lower surface of the encapsulation layer ENC can further penetrate at the interface between the cathode electrode CAT and the planarization layer PL, and can transfer into the dummy emission layer DEL. The moisture or hydrogen particles can diffuse along the dummy emission layer DEL. However, since the dummy emission layer DEL is disconnected from the emission layer EL due to the trench TR and the under-cut UC, the moisture and hydrogen particles may not diffuse into the emission layer EL.

The first example aspect propose a structure in which a scan line under-cut SUC, a data line under-cut DUC or a driving line under-cut VUD are formed together with the under-cut UC along the trench TR. However, it is not limited thereto. As an example, only under-cut UC can be formed along the trench TR without the scan line under-cut SUC, the data line under-cut DUC or the driving line under-cut VUD. In this case, a shorting bar which is an element reducing or preventing the static electricity of the scan line under-cut SUC, the data line under-cut DUC or the driving line under-cut VUD can be configured with different element/structure.

According to the light emitting display device according to the first example aspect, the pattern electrode PAT and the scan line SL can be connected by a single metal layer at the initial stage of the manufacturing process, and then the pattern electrode PAT and the scan line SL are separated while forming the trench TR. When the scan line SL is connected to the pattern electrode PAT, the pattern electrode PAT surrounding at least three sides of the display area AA can be a shorting-bar that discharges static electricity generated during the manufacturing process to outside.

Since the product is completed after forming the anode electrode ANO, it is necessary to separate all scan lines SL connected to the pattern electrode PAT. The light emitting display device according to the present disclosure further forms an under-cut UC at the pattern electrode PAT in the process of separating the scan lines SL from the pattern electrode PAT, thereby the emission layer EL deposited later can be disconnected between the display area AA and the non-display area NDA.

When the emission layer EL made of organic material is deposited to connect some portion of the non-display area NDA and the entire display area AA, impurities such as moisture and hydrogen particles penetrating from the edge of the substrate 110 can spread or diffuse into the pixels P disposed within the display area AA along the emission layer EL. As a result, the light emitting diodes OLE formed in the pixels P can be damaged and the lifespan of the display device can be shortened. However, as in the first example aspect, the connectivity of the emission layer EL is cut off or disconnected by the trench TR and the under-cut UC formed at the boundary area BDA, so moisture and hydrogen particles intruded from the outside can be reduced or prevented from diffusing into the display area AA. Moreover, since the under-cut UC at the bottom of the trench TR can be covered by the cathode electrode CAT, which is an inorganic material, and the cathode electrode CAT can cover the emission layer EL made of an organic material, the first example aspect can have a structure for blocking moisture from penetrating from the outside and diffusing into the display device.

### Second Example Aspect

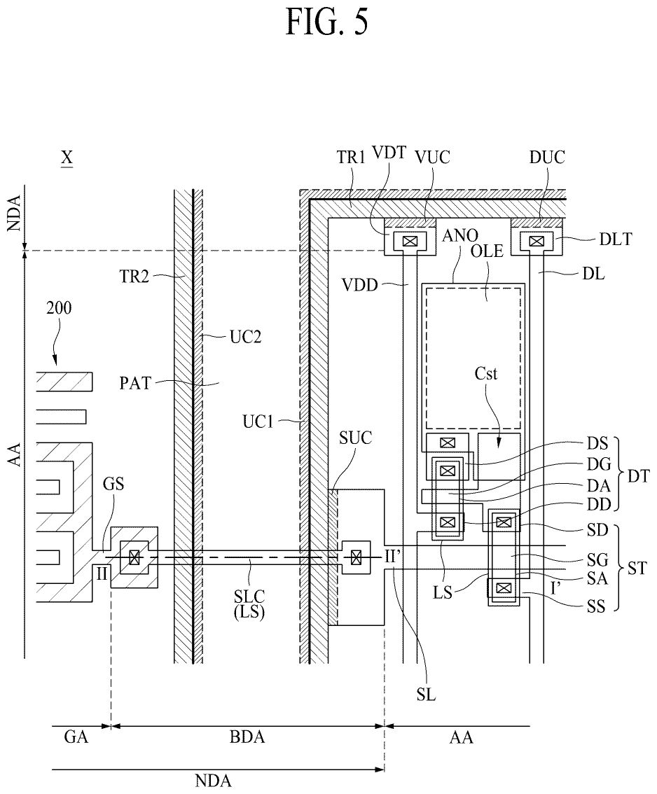

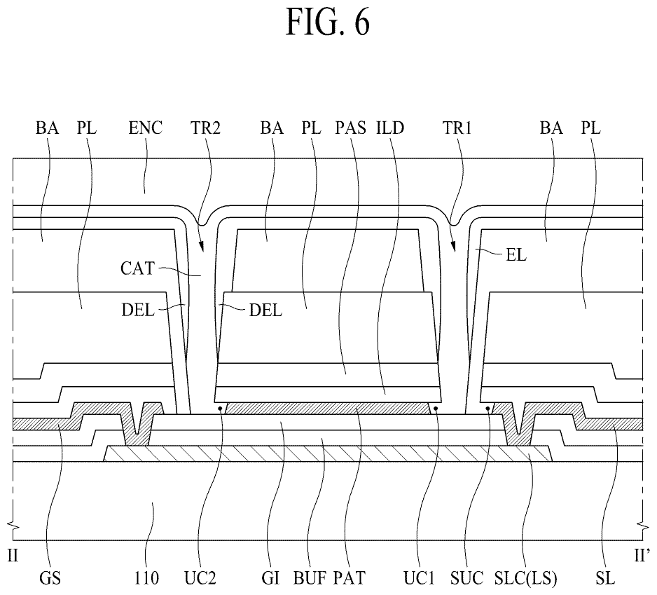

Hereinafter, referring to FIG. 5 and FIG. 6, a light emitting display device according to a second example aspect of the present disclosure will be explained. FIG. 5 is an enlarged plan view of dotted box ‘X’ in FIG. 1, illustrating a structure of a light emitting display device according to the second example aspect of the present disclosure. FIG. 6 is an enlarged cross-sectional view, along the cutting line II-II′ in FIG. 5, illustrating a structure of a light emitting display device according to the second example aspect of the present disclosure. In the second example aspect, the descriptions of parts that are the same as those of the first example aspect are not duplicated. Since the structure inside the pixel area is the same as the first example aspect, it will be omitted or briefly described. The description will focus on parts where the features of the second example aspect are shown.

The light emitting display device according to the second example aspect can include a display area AA and a non-display area NDA defined on a substrate 110. The display area AA can include a plurality of scan lines SL, a plurality of data lines DL and a plurality of driving current lines VDD for defining a plurality of pixels P. Each pixel P can include a switching thin film transistor ST, a driving thin film transistor DT and a storage capacitor Cst.

The non-display area NDA can include a gate driving area GA and a boundary area BDA. The gate driving area GA can include a gate driver 200. The boundary area BDA can include a pattern electrode PAT and a link line SLC. The pattern electrode PAT can have a bent segment shape having a predetermined width surrounding the display area AA. The link line SLC can be the line connecting the gate signal line GS outputting the gate signal from the gate driver 200 to the scan line SL.

Unlike the first example aspect, in the second example aspect, each of parallel two sides of the pattern electrode PAT can have under-cut. For example, a first under-cut UC1 can be disposed at the first side of the pattern electrode PAT near to the display area AA, and a second under-cut UC2 can be disposed at the second side of the pattern electrode PAT near to the gate driving area GA.

Further, trenches are formed along the under-cuts. For example, a first trench TR1 can be formed along the first under-cut UC1, and a second trench TR2 can be formed along the second under-cut UC2. The first under-cut UC1 and the second under-cut UC2 are elements made by the first trench TR1 and the second trench TR2, respectively.

For example, the first trench TR1 can be formed by removing the insulating layer covering the pattern electrode PAT along the first side of the pattern electrode PAT near to the display area AA. The second trench TR2 can be formed by removing the insulating layer covering the pattern electrode PAT along the second side of the pattern electrode PAT near to the gate driving area GA. After that, by over-etching the sides of the pattern electrode PAT exposed from the first trench TR1 and the second trench TR2, the first under-cut UC1 and the second under-cut UC2 can be formed.

Here, like the first example aspect, a driving terminal VDT connected to the driving current line VDD can be disposed at the upper end of the driving current line VDD and, a data terminal DLT connected to the data line DL can be disposed at the upper end of the data line DL. The driving terminal VDT and the data terminal DLT can be connected to the pattern electrode PAT at initial stage. As forming the first trench TR1 and the first under-cut UC1, the driving terminal VDT and the data terminal DLT can be separated from the pattern electrode PAT. In addition, when forming the first under-cut UC1, by the over-etching process, a driving line under-cut VUC and a data line under-cut DUC having the same structure as the scan line under-cut SUC can be formed.

Hereinafter, referring to FIG. 6, a cross-sectional structure of the boundary area BDA one of main features of the light emitting display device according to the second example aspect will be explained.

A link line SLC (e.g., a link line SLC made of the same material with the light shielding layer LS) can be formed on the substrate 110. A buffer layer BUF and a gate insulating layer GI can be sequentially deposited on the link line SLC. A gate signal line GS, a scan line SL and a pattern electrode PAT can be formed on the gate insulating layer GI. The gate signal line GS can be connected to one end of the link line SLC via a contact hole penetrating the buffer layer BUF and the gate insulating layer GI. The scan line SL can be connected to another end of the link line SLC via another contact hole penetrating the buffer layer BUF and the gate insulating layer GI. The pattern electrode PAT can be disposed between the gate signal line GS and the scan line SL. The pattern electrode PAT can be spaced apart from the gate signal line GS and the scan line SL with a certain distance.

An intermediate insulating layer ILD, a passivation layer PAS and a planarization layer PL can be sequentially deposited on the gate signal line GS, the scan line SL and the pattern electrode PAT. The first trench TR1 and the second trench TR2 can be formed at the intermediate insulating layer ILD, the passivation layer PAS and the planarization layer PL. The first trench TR1 can be disposed between the first side of the pattern electrode PAT and the end of the scan line SL. The second trench TR2 can be disposed between the second side of the pattern electrode PAT and the end of the gate signal line GS.

The first under-cut UC1 and the scan line under-cut SUC can be formed at the first trench TR1. The first under-cut UC1 can be a space formed by etching or eroding the first side of the pattern electrode PAT into the lower part of the intermediate insulating layer ILD. The scan line under-cut SUC can be a space formed by etching or eroding end of the scan line SL into the lower part of the intermediate insulating layer ILD.

The second under-cut UC2 can be formed at the second trench TR2. The second under-cut UC2 can be a space formed by etching or eroding the second side of the pattern electrode PAT into the lower part of the intermediate insulating layer ILD. The end of the gate signal line GS may not have under-cut. However, it is not limited thereto. An under-cut having the same shape as end of the scan line SL can be formed at the end of the gate signal line GS.

A bank BA can be formed on the planarization layer PL. The bank BA can be formed as covering the etched sidewalls of the planarization layer PL, the passivation layer PAS and the intermediate insulating layer ILD, and the scan line under-cut SUC, at the end of the scan line SL. On the contrary, the bank BA may not cover the first under-cut UC1 and the second under-cut UC2 on the planarization layer PL covering the pattern electrode PAT. For example, on the pattern electrode PAT, the bank BA can have smaller width than the planarization layer PL. Further, the bank BA can cover the etched sidewalls of the planarization layer PL, the passivation layer PAS and the intermediate insulating layer ILD, at the end of the gate signal line GS. For example, the bank BA can cover the sidewall where the gate signal line GS is disposed at the second trench TR2, and extend to the bottom of the second trench TR2.

As a result, the bank BA can be formed as exposing the first under-cut UC1 and the second under-cut UC2 at the first trench TR1 and the second trench TR2. An emission layer EL and a dummy emission layer DEL can be formed on the bank BA. The emission layer EL can be disposed on the bank BA covering the scan line SL. The dummy emission layer DEL can be disposed on the bank BA covering the pattern electrode PAT and the bank BA covering the gate signal line GS. The emission layer EL and the dummy emission layer DEL can be disconnected by the first trench TR1 and the second trench TR2. Further, the dummy emission layer DEL can be divided by the second trench TR2 and the second under-cut UC2.

A cathode electrode CAT can be deposited on the emission layer EL and the dummy emission layer DEL disconnected from each other by the first trench TR1 and the second trench TR2. The cathode electrode CAT can be deposited as a common layer that fills the first trench TR1 and the second trench TR2, and can be connected from the entire display area AA to some of the non-display area NDA.

The cathode electrode CAT can fill into the first under-cut UC1 inside of the first trench TR1 so as to be connected to the first side of the pattern electrode PAT. Further, by filling the second under-cut UC2 inside of the second trench TR2, the cathode electrode CAT can be connected to the second side of the pattern electrode PAT. On the contrary, the scan line under-cut SUC can be filled with the bank BA, so the cathode electrode CAT may not be connected to the scan line SL. Like this, the cathode electrode CAT may not be connected to the gate signal line GS. Embodiments are not limited thereto. As an example, the bank BA may expose only one of the first under-cut UC1 and the second under-cut UC2. In this case, the cathode electrode CAT may be connected to only one side of the pattern electrode PAT at the exposed one of the first under-cut UC1 and the second under-cut UC2, without being limited thereto.

An encapsulation layer ENC can be disposed on the cathode electrode CAT. The encapsulation layer ENC can reduce or prevent moisture or hydrogen particles from penetrating into the dummy emission layer DEL from the outside environment. However, at the outermost end portion where the encapsulation layer ENC and the planarization layer PL or the bank BA are met, moisture or hydrogen particles can penetrate. Moisture or hydrogen particles penetrated through the lower surface of the encapsulation layer ENC can further penetrate at the interface between the cathode electrode CAT and the planarization layer PL, and can transfer into the dummy emission layer DEL. The moisture or hydrogen particles can diffuse along the dummy emission layer DEL. However, since the dummy emission layer DEL is disconnected by the second trench TR2 and the second under-cut UC2, the moisture and hydrogen particles may not diffuse any more.

By any defects on the second trench TR2 and the second under-cut UC2, moisture or hydrogen particles can diffuse through the dummy emission layer DEL. Even so, since the dummy emission layer DEL is also disconnected from the emission layer EL due to the first trench TR1 and the first under-cut UC1, the moisture and hydrogen particles may not diffuse into the emission layer EL.

In the light emitting display device according to the second example aspect, the pattern electrode PAT and the scan line SL can be connected as a single metal layer at the initial stage of the manufacturing process, and then the pattern electrode PAT and the scan line SL are separated while forming the first trench TR1. When the scan line SL is connected to the pattern electrode PAT, the pattern electrode PAT surrounding at least three sides of the display area AA can be a shorting-bar that discharges static electricity generated during the manufacturing process to outside.

Since the product is completed after forming the anode electrode ANO, it is necessary to separate all scan lines SL connected to the pattern electrode PAT. In the process of separating the scan lines SL from the pattern electrode PAT, a first under-cut UC1 and a second under-cut UC2 are formed at the pattern electrode PAT, thereby the emission layer EL deposited later can be disconnected between the display area AA and the non-display area NDA.

When the emission layer EL made of organic material is deposited to extend from some portion of the non-display area NDA to the entire display area AA, impurities such as moisture and hydrogen particles penetrating from the edge of the substrate 110 can spread or diffuse into the pixels P disposed within the display area AA along the emission layer EL. As a result, the light emitting diodes OLE formed in the pixels P can be damaged and the lifespan of the display device can be shortened. However, as in the second example aspect, the connectivity of the dummy emission layer DEL and/or the emission layer EL is cut off or disconnected by the first trench TR1, the first under-cut UC1, the second trench TR2 and the second under-cut UC2 formed at the boundary area BDA, so moisture and hydrogen particles intruded from the outside can be reduced or prevented from diffusing into the display area AA along the dummy emission layer DEL and/or emission layer EL. Moreover, since the first under-cut UC1 at the bottom of the first trench TR1 and the second under-cut UC2 at the bottom of the second trench TR2 can be covered by the cathode electrode CAT, which is an inorganic material, the second example aspect can have a structure for blocking moisture from penetrating from the outside and diffusing into the display device.

### Third Example Aspect

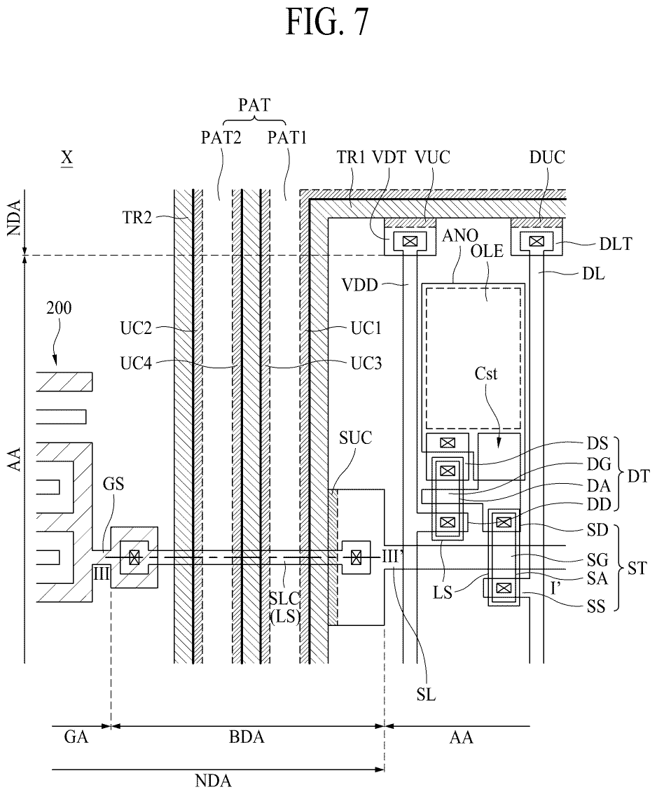

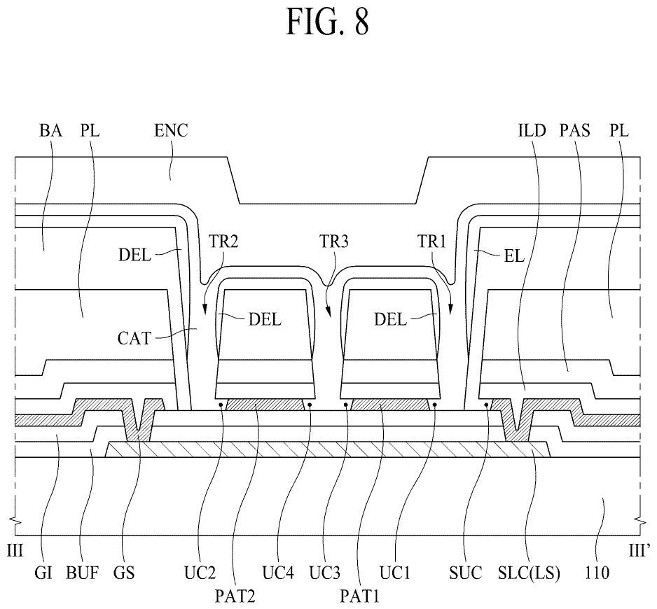

Hereinafter, referring to FIG. 7 and FIG. 8, a light emitting display device according to a third example aspect will be explained. FIG. 7 is an enlarged plan view of dotted box ‘X’ in FIG. 1, illustrating a structure of a light emitting display device according to the third example aspect of the present disclosure. FIG. 8 is an enlarged cross-sectional view, along the cutting line III-III′ in FIG. 7, illustrating a structure of a light emitting display device according to the third example aspect of the present disclosure.

The light emitting display device according to the third example aspect can have a very similar structure with that of the second example aspect. The difference can be that the light emitting display device according to the third example aspect can have divided pattern electrodes PAT into two bodies. Therefore, elements having the same structure with the second example aspect may not be duplicated or simply mentioned.

The light emitting display device according to the second example aspect can include a display area AA and a non-display area NDA defined on a substrate 110. The non-display area NDA can include a gate driving area GA and a boundary area BDA. The gate driving area GA can include a gate driver 200. The boundary area BDA can include a pattern electrode PAT and a link line SLC.

A first trench TR1 and a first under-cut UC1 can be disposed at the first side of the pattern electrode PAT near to the display area AA, and a second trench TR2 and a second under-cut UC2 can be disposed at the second side of the pattern electrode PAT near to the gate driving area GA. The first trench TR1 can be formed by removing the insulating layer covering the pattern electrode PAT along the first side of the pattern electrode PAT near to the display area AA. The second trench TR2 can be formed by removing the insulating layer covering the pattern electrode PAT along the second side of the pattern electrode PAT near to the gate driving area GA. After that, by over-etching the sides of the pattern electrode PAT exposed from the first trench TR1 and the second trench TR2, the first under-cut UC1 and the second under-cut UC2 can be formed.

Here, like the second example aspect, a driving terminal VDT connected to the driving current line VDD can be disposed at the upper end of the driving current line VDD and, a data terminal DLT connected to the data line DL can be disposed at the upper end of the data line DL. Further, when forming the first under-cut UC1, by the over-etching process, a driving line under-cut VUC and a data line under-cut DUC having the same structure as the scan line under-cut SUC can be formed.

In the third example aspect, the pattern electrode PAT are divided into two bodies. However, it is not limited thereto. The pattern electrode PAT can be divided into multiple bodies. Here, for convenience, the pattern electrode PAT can be described as including a first pattern electrode PAT1 and a second pattern electrode PAT2.

The first pattern electrode PAT1 can be disposed near the display area AA, and the second pattern electrode PAT2 can be disposed near the gate driving area GA be apart from the first pattern electrode PAT1 with a predetermined distance. A first trench TR1 can be disposed between the first pattern electrode PAT1 and the display area AA. A second trench TR2 can be disposed between the second pattern electrode PAT2 and the gate driving area GA. A third trench TR3 can be disposed between the first pattern electrode PAT1 and the second pattern electrode PAT2. A first under-cut UC1 and a scan line under-cut SUC can be formed by the first trench TR1, and a second under-cut UC2 can be formed by the second trench TR2. Further, by the third trench TR3, a third under-cut UC3 can be formed at the first pattern electrode PAT1 and a fourth under-cut UC3 can be formed at the second pattern electrode PAT2.

Hereinafter, referring to FIG. 8, the cross-sectional structure of the boundary area BDA as one of the main features of the light emitting display device according to the third example aspect will be explained.

A link line SLC (e.g., a link line SLC made of the same material with the light shielding layer LS) can be formed on the substrate 110. A buffer layer BUF and a gate insulating layer GI can be sequentially deposited on the link line SLC. A gate signal line GS, a scan line SL and a pattern electrode PAT can be formed on the gate insulating layer GI. The gate signal line GS can be connected one end of the link line SLC via a contact hole penetrating the buffer layer BUF and the gate insulating layer GI. The scan line SL can be connected to another end of the link line SLC via another contact hole penetrating the buffer layer BUF and the gate insulating layer GI. The pattern electrode PAT can be disposed between the gate signal line GS and the scan line SL. The pattern electrode PAT can be spaced apart from the gate signal line GS and the scan line SL with a certain distance.

The pattern electrode PAT can be divided into a first pattern electrode PAT1 and a second pattern electrode PAT2. The first pattern electrode PAT1 can be apart from the scan line SL with a first predetermined distance, the second pattern electrode PAT2 can be apart from the gate signal line GS with a second predetermined distance. Further, the first pattern electrode PAT1 can be apart from the second pattern electrode PAT2 with a third predetermined distance. As an example, the first predetermined distance, the second predetermined distance and the third predetermined distance may be equal to or different from each other.

An intermediate insulating layer ILD, a passivation layer PAS and a planarization layer PL can be sequentially deposited on the gate signal line GS, the scan line SL and the pattern electrode PAT. The first trench TR1, the second trench TR2 and the third trench TR3 can be formed at the intermediate insulating layer ILD, the passivation layer PAS and the planarization layer PL. The first trench TR1 can be disposed between the first pattern electrode PAT1 and the scan line SL. The second trench TR2 can be disposed between the second pattern electrode PAT2 and the gate signal line GS. The third trench TR3 can be disposed between the first pattern electrode PAT1 and the second pattern electrode PAT2.

The first under-cut UC1 and the scan line under-cut SUC can be formed at the first trench TR1. The first under-cut UC1 can be a space formed by etching or eroding the first side of the first pattern electrode PAT1 into the lower part of the intermediate insulating layer ILD. The scan line under-cut SUC can be a space formed by etching or eroding end of the scan line SL into the lower part of the intermediate insulating layer ILD.

The second under-cut UC2 can be formed at the second trench TR2. The second under-cut UC2 can be a space formed by etching or eroding the second side of the second pattern electrode PAT2 into the lower part of the intermediate insulating layer ILD. The end of the gate signal line GS may not have under-cut. However, it is not limited thereto. An under-cut having the same shape as end of the scan line SL can be formed at the end of the gate signal line GS.

The third under-cut UC3 and the fourth under-cut UC4 can be formed at the third trench TR3. The third under-cut UC3 can be a space formed by etching or eroding the second side of the first pattern electrode PAT1 into the lower part of the intermediate insulating layer ILD. The fourth under-cut UC4 can be a space formed by etching or eroding the second side of the second pattern electrode PAT2 into the lower part of the intermediate insulating layer ILD.

A bank BA can be formed on the planarization layer PL. The bank BA can be formed as covering the etched sidewalls of the planarization layer PL, the passivation layer PAS and the intermediate insulating layer ILD, and the scan line under-cut SUC, at the end of the scan line SL. For example, the bank BA may cover all sidewalls where the scan line SL is disposed in the first trench TR1, and extend to the bottom of the second trench TR1. Further, the bank BA can be formed as covering the etched sidewalls of the planarization layer PL, the passivation layer PAS and the intermediate insulating layer ILD at the end of the gate signal line GS. For example, the bank BA can cover all sidewalls where the gate signal line GS is disposed in the second trench TR2, and extend to the bottom of the second trench TR2.

On the contrary, on the planarization layer PL covering the pattern electrode PAT, the bank BA may not be disposed. For example, on the first pattern electrode PAT1 and the second pattern electrode PAT2, the intermediate insulating layer ILD, the passivation layer PAS and the planarization layer PL are deposited only. However, it is not limited thereto. The bank BA can be formed on the pattern electrode PAT with smaller width than the planarization layer PL.

As a result, the bank BA can be formed as exposing the first under-cut UC1 and the second under-cut UC2 at the first trench TR1 and the second trench TR2. Further, the third under-cut UC3 and the fourth under-cut UC4 can be exposed at the third trench TR3. Embodiments are not limited thereto. As an example, the bank BA may be formed as exposing only one among the first under-cut UC1, the second under-cut UC2, the third under-cut UC3 and the fourth under-cut UC4. As an example, the bank BA may be formed as exposing only one of the first under-cut UC1 and the third under-cut UC3 and one of the second under-cut UC2 and the fourth under-cut UC4. An emission layer EL and a dummy emission layer DEL can be deposited on the planarization layer PL and the bank BA. The emission layer EL can be disposed on the bank BA covering the scan line SL. The dummy emission layer DEL can be disposed on the planarization layer PL covering the first pattern electrode PAT1 and the planarization layer PL covering the second pattern electrode PAT2. Further, the dummy emission layer DEL can be disposed on the bank BA covering the gate signal line GS. The emission layer EL and the dummy emission layer DEL can be disconnected by the first trench TR1 and the first under-cut UC1. The dummy emission layer DEL can be disconnected by the second trench TR2 and the second under-cut UC2. Moreover, the dummy emission layer DEL can be further disconnected by the third trench TR3, the third under-cut UC3 and the fourth under-cut UC4.

A cathode electrode CAT can be deposited on the emission layer EL and the dummy emission layer DEL of which connectivity is disconnected by the first trench TR1, the second trench TR2 and the third trench TR3. The cathode electrode CAT can be deposited as a common layer that fills the first trench TR1, the second trench TR2 and the third trench TR3, and can be connected from the entire display area AA to some of the non-display area NDA. As an example, the cathode electrode CAT may be continuous at each of the first trench TR1, the second trench TR2 and the third trench TR3. As an example, the cathode electrode CAT may extend to the bottom of each of the first trench TR1, the second trench TR2 and the third trench TR3. Embodiments are not limited thereto. As an example, the cathode electrode CAT may extend to the bottom of at least one of the first trench TR1, the second trench TR2 and the third trench TR3. As an example, the cathode electrode CAT may extend to the bottom of at least one of the first trench TR1, the second trench TR2 and the third trench TR3 corresponding to the exposed one of the first under-cut UC1, the second under-cut UC2, the third under-cut UC3 and the fourth under-cut UC4.

The cathode electrode CAT can fill into the first under-cut UC1 inside of the first trench TR1 so as to be connected to the first pattern electrode PAT1. Further, by filling the second under-cut UC2 inside of the second trench TR2, the cathode electrode CAT can be connected to the second pattern electrode PAT2. In addition, by filling the third under-cut UC3 and the fourth under-cut UC4 inside of the third trench TR3, the cathode electrode CAT can be connected to the first pattern electrode PAT1 and the second pattern electrode PAT2. On the contrary, the scan line under-cut SUC can be filled with the bank BA, so the cathode electrode CAT may not be connected to the scan line SL. Like this, the cathode electrode CAT may not be connected to the gate signal line GS.

An encapsulation layer ENC can be disposed on the cathode electrode CAT. At the outermost end portion where the encapsulation layer ENC and the planarization layer PL (or the bank BA) are met, moisture or hydrogen particles can penetrate. Moisture or hydrogen particles penetrated through the lower surface of the encapsulation layer ENC can further penetrate at the interface between the cathode electrode CAT and the planarization layer PL, and can transfer into the dummy emission layer DEL. The moisture or hydrogen particles can diffuse along the dummy emission layer DEL. However, since the dummy emission layer DEL is disconnected by the second trench TR2 and the second under-cut UC2, the moisture and hydrogen particles may not diffuse any more.

By any defects on the second trench TR2 and the second under-cut UC2, moisture or hydrogen particles can diffuse through the dummy emission layer DEL. Even so, since the connectivity of the dummy emission layer DEL is further disconnected by the third trench TR3, the third under-cut UC3 and the fourth under-cut UC4, the moisture and hydrogen particles may not diffuse into the dummy emission layer DEL. Moreover, by any defects on the third trench TR3, the emission layer EL can be disconnected from the dummy emission layer DEL by the first trench TR1 and the first under-cut UC1, so the moisture and hydrogen particles may not diffuse into the emission layer EL.

In the light emitting display device according to the third example aspect, the pattern electrode PAT and the scan line SL can be connected as a single metal layer at the initial stage of the manufacturing process, and then the pattern electrode PAT and the scan line SL are separated while forming the first trench TR1, the second trench TR2 and the third trench TR3. When the scan line SL is connected to the pattern electrode PAT, the pattern electrode PAT surrounding at least three sides of the display area AA can be a shorting-bar that discharges static electricity generated during the manufacturing process to outside.

Since the product is completed after forming the anode electrode ANO, it is necessary to separate all scan lines SL connected to the pattern electrode PAT. In the process of separating the scan lines SL from the pattern electrode PAT, the pattern electrode PAT is divided into the first pattern electrode PAT1 and the second pattern electrode PAT2, and the first under-cut UC1, the second under-cut UC2, the third under-cut UC3 and the fourth under-cut UC4 are formed at the pattern electrode PAT, thereby the emission layer EL deposited later can be disconnected between the display area AA and the non-display area NDA.

When the emission layer EL made of organic material is deposited to extend from some portion of the non-display area NDA to the entire display area AA, impurities such as moisture and hydrogen particles penetrating from the edge of the substrate 110 can spread or diffuse into the pixels P disposed within the display area AA along the emission layer EL. As a result, the light emitting diodes OLE formed in the pixels P can be damaged and the lifespan of the display device can be shortened. However, as in the third example aspect, the connectivity of the dummy emission layer DEL and/or the emission layer EL is cut off or disconnected by the first trench TR1 and the first under-cut UC1, the second trench TR2 and the second under-cut UC2, and the third trench TR3, the third under-cut UC3 and the fourth under-cut UC4 formed at the boundary area BDA, so moisture and hydrogen particles intruded from the outside can be reduced or prevented from diffusing into the display area AA along the dummy emission layer DEL and/or emission layer EL. Moreover, since the first under-cut UC1 at the bottom of the first trench TR1, the second under-cut UC2 at the bottom of the second trench TR2 and the third under-cut UC3 and the fourth under-cut UC4 at the bottom of the third trench TR3 can be covered by the cathode electrode CAT, which is an inorganic material, the second example aspect can have a structure for blocking moisture from penetrating from the outside and diffusing into the display device.

### Fourth Example Aspect

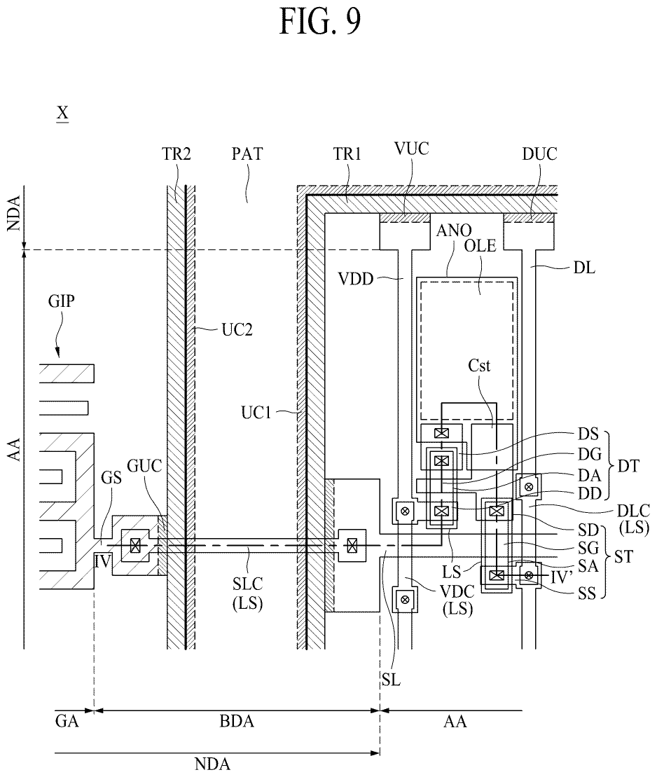

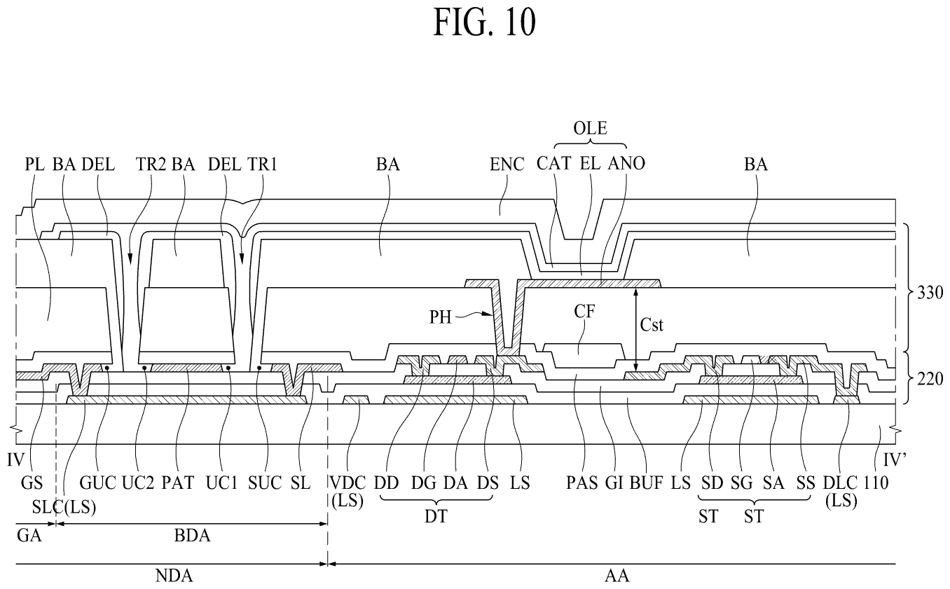

Hereinafter, referring to FIG. 9 and FIG. 10, a light emitting display device according to a fourth example aspect will be explained. FIG. 9 is an enlarged plan view of dotted box ‘X’ in FIG. 1, illustrating a structure of a light emitting display device according to the fourth example aspect of the present disclosure. FIG. 10 is an enlarged cross-sectional view, along the cutting line IV-IV′ in FIG. 9, illustrating a structure of a light emitting display device according to the fourth example aspect of the present disclosure.

The light emitting display device according to the fourth example aspect of the present disclosure as shown in FIG. 9 and FIG. 10 can have very similar structure to that of the second example aspect as shown in FIG. 5 and FIG. 6. In particular, the elements disposed in the boundary area BDA including main features of the present disclosure can have the same or substantially the same structure.

The difference is that, in the fourth example aspect, the data line DL and the driving current line VDD can be made of same material and disposed at the same layer with the scan line SL. The data line DL and the scan line SL, which are orthogonal to each other and transmit different signals, may not be formed of the same material on the same layer at least at the intersections thereof. Therefore, a portion of the data line DL that intersects the scan line SL can be cut off, and a data link line DLC can be formed at the same layer as the light shielding layer LS and connected to the data line DL. Likewise, a portion of the driving current line VDD that intersects the scan line SL can be cut off, and a driving link line VDC is formed at the same layer as the light shielding layer LS and connected to the driving current line VDD. Embodiments are not limited thereto. As an example, the data link line DLC and the driving link line VDC may be formed at a different layer from that of the light shielding layer LS.

The driving current line VDD and the data line DL can be made of same material and disposed on the same layer with the scan line SL. Therefore, like the scan line SL, the driving current line VDD and the data line DL can be connected to the pattern electrode PAT at the initial stage and then by forming the first trench TR1 and the first under-cut UC1, they can be separated from the pattern electrode PAT. When forming the first under-cut UC1, as an example, each end portion of the scan line SL, the driving current line VDD and the data line DL forwarding to the pattern electrode PAT can be over-etched at the same time, so a scan line under-cut SUC, a driving line under-cut VUC and a data line under-cut DUC can be formed with the same or substantially the same structure.

Further, the gate signal line GS can be also connected to the pattern electrode PAT at the initial stage, and then by forming a second trench TR2 and the second under-cut UC2, it can be separated from the pattern electrode PAT. When forming the second under-cut UC2, the end portion of the gate signal line GS forwarding to the pattern electrode PAT can be over-etched to form a gate signal under-cut GUC with the same structure with the scan or substantially the same line under-cut SUC.

Referring to FIG. 10, the cross-sectional structure of the light emitting display device according to the fourth example aspect will be explained. The light emitting display device can include a substrate 110, a driving element layer 220, a light emitting element layer 330 and an encapsulation layer ENC. The driving element layer 220 can include a plurality of layers deposited and/or formed on the substrate 110. The driving element layer d220 can include a switching thin film transistor ST and a driving thin film transistor DT.

In detail, a light shielding layer LS can be formed on the substrate 110. The light shielding layer LS can be disposed as an island shape overlapping with the semiconductor layer SA of the switching thin film transistor ST and the semiconductor layer DA of the driving thin film transistor DT. At the boundary area BDA, a link line SLC made of the same material with the light shielding layer LS can be formed. The link line SLC can be a line for linking the gate signal line GS to the scan line SL.

Further, a data link line DLC and driving link line VDC made of the same material with the light shielding layer LS can be formed in the display area AA. The data link line DLC can connect the disconnected portion of data line DL at the area overlapping with the scan line SL. The driving link line VDC can connect the disconnected portion of the driving current line VDD at the area overlapping with the scan line SL.

A buffer layer BUF can be deposited on the light shielding layer LS, the link line SLC, the data link line DLC and the driving link line VDC as covering entire surface of the substrate 110. A semiconductor layer SA of the switching thin film transistor ST and a semiconductor layer DA of the driving thin film transistor DT can be formed on the buffer layer BUF. The channel areas of the semiconductor layers SA and DA can be overlapped with the light shielding layer LS.

A gate insulating layer GI can be deposited on the substrate 110 having the semiconductor layers SA and DA. A gate electrode SG overlapping with the semiconductor layer SA of the switching thin film transistor ST and a gate electrode DG overlapping with the semiconductor layer DA of the driving thin film transistor DT can be formed on the gate insulating layer GI. In addition, the scan line SL and the gate signal line GS can be formed on the gate insulating layer GI. The scan line SL can be disposed in the display area AA and the gate signal line GS can be disposed in the non-display area NDA. A source electrode SS connected to one side of the semiconductor layer SA and a drain electrode SD connected to another side of the semiconductor layer SA can be formed at opposite sides of and separated from the gate electrode SG of the switching thin film transistor ST. A source electrode DS connected to one side of the semiconductor layer DA and a drain electrode DD connected to another side of the semiconductor layer DA can be formed at opposite sides of the gate electrode DG of and separated from the driving thin film transistor DT.

The gate electrode SG and DG and the source-drain electrodes SS-SD and DS-DD can be formed on the same layer, but they are spatially and electrically separated from each other, without being limited thereto. The source electrode SS of the switching thin film transistor ST can be connected to the data line DL via a contact hole penetrating the gate insulating layer GI. The drain electrode DD of the driving thin film transistor DT can be connected to the driving current line VDD via a contact hole penetrating the gate insulating layer GI.

A passivation layer PAS can be deposited on the substrate 110 having the thin film transistors ST and DT. The passivation layer PAS can be formed of silicon oxide and/or silicon nitride. A color filter CF can be formed on the passivation layer PAS.

The light emitting element layer 330 can be formed on the driving element layer 220. The light emitting element layer 330 can include a planarization layer PL and a light emitting diode OLE. A pixel contact hole PH can be formed at the passivation layer PAS and the planarization layer PL to expose a portion of the source electrode DS of the driving thin film transistor DT.

An anode electrode (or pixel electrode) ANO can be formed on the upper surface of the planarization layer PL. The anode electrode ANO can be connected to the source electrode DS of the driving thin film transistor DT via the pixel contact hole PH.

A bank BA can be formed on the substrate 110 having the anode electrode ANO. The bank BA can cover circumferences of the anode electrode ANO to expose most middle portion of the anode electrode ANO.

An emission layer EL can be deposited on the anode electrode ANO and the bank BA. The emission layer EL can be deposited over entire display area AA as covering the anode electrode ANO and the bank BA.

A cathode electrode (or common electrode) CAT can be deposited on entire surface of the substrate 110 having the emission layer EL. The cathode electrode CAT can be deposited as being surface contacting with the emission layer EL. The cathode electrode CAT can be formed across the entire substrate 110 to be commonly connected to the emission layer EL formed in all pixels.

An encapsulation layer ENC can be disposed on the light emitting element layer 220. The encapsulation layer ENC can reduce or prevent moisture or hydrogen particles from penetrating into the dummy emission layer DEL and the emission layer EL from the outside environment. At the outermost end where the encapsulation layer ENC and the planarization layer PL (or the bank BA) are met, moisture or hydrogen particles can penetrate. Moisture or hydrogen particles penetrated through the lower surface of the encapsulation layer ENC can further penetrate at the interface between the cathode electrode CAT and the planarization layer PL, and can transfer into the dummy emission layer DEL. The moisture or hydrogen particles can diffuse along the dummy emission layer DEL. However, since the dummy emission layer DEL is disconnected from the emission layer EL due to the second trench TR2 and the second under-cut UC2, the moisture and hydrogen particles may not diffuse any more.

By any defects on the second trench TR2 and the second under-cut UC2, moisture or hydrogen particles can diffuse through the dummy emission layer DEL. Even so, since the dummy emission layer DEL is disconnected from the emission layer EL due to the first trench TR1 and the first under-cut UC1, the moisture and hydrogen particles may not diffuse into the emission layer EL.

In the fourth example embodiment, the first trench TR1 and the first under-cut UC1 can be formed at the first side of the pattern electrode PAT, and the second trench TR2 and the second under-cut UC2 can be formed at the second side of the pattern electrode PAT. However, it is not limited thereto. In some cases, the first trench TR1 and the first under-cut UC1 can be formed without the second trench TR2 and the second under-cut UC2. Otherwise, the second trench TR2 and the second under-cut UC2 can be formed without the first trench TR1 and the first under-cut UC1. When only first trench TR1 and the first under-cut UC1 are formed, the scan line under-cut SUC can be formed at the end of the scan line SL facing the pattern electrode PAT, the driving line under-cut VUD can be formed at the end of the driving current line VDD, and the data line under-cut DUC can be formed at the end of the data line DL. Further, as an example, when the second trench TR2 and the second under-cut UC2 may be formed without the first trench TR1 and the first under-cut UC1, a gate signal under-cut GUC can be formed at the end of the gate signal line GS.

### Fifth Example Aspect

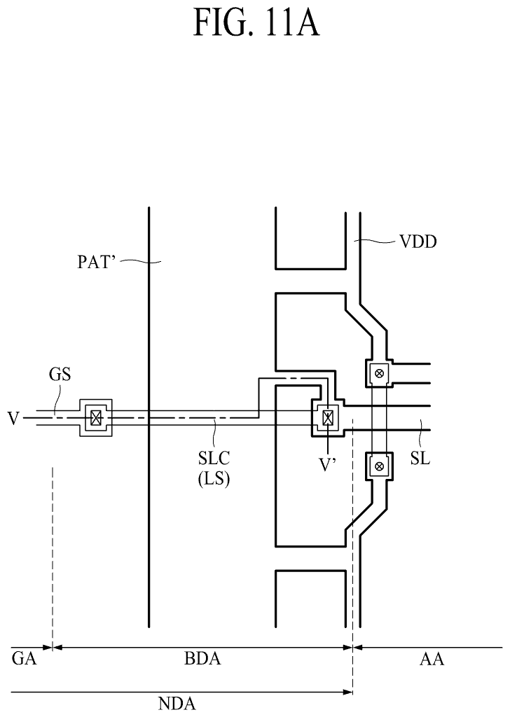

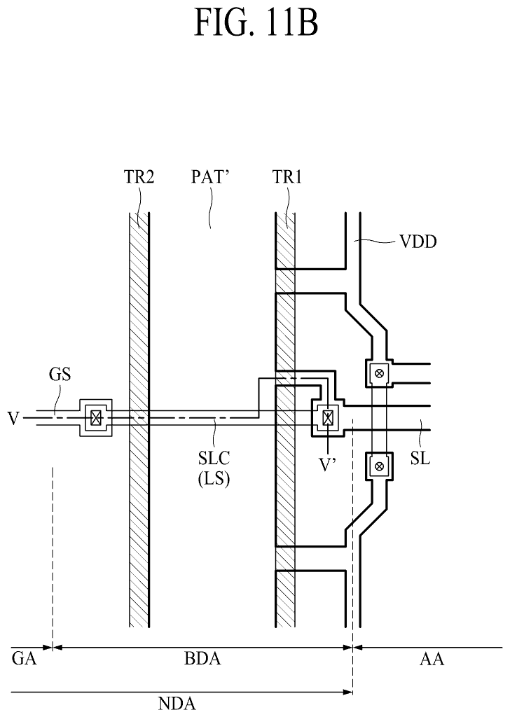

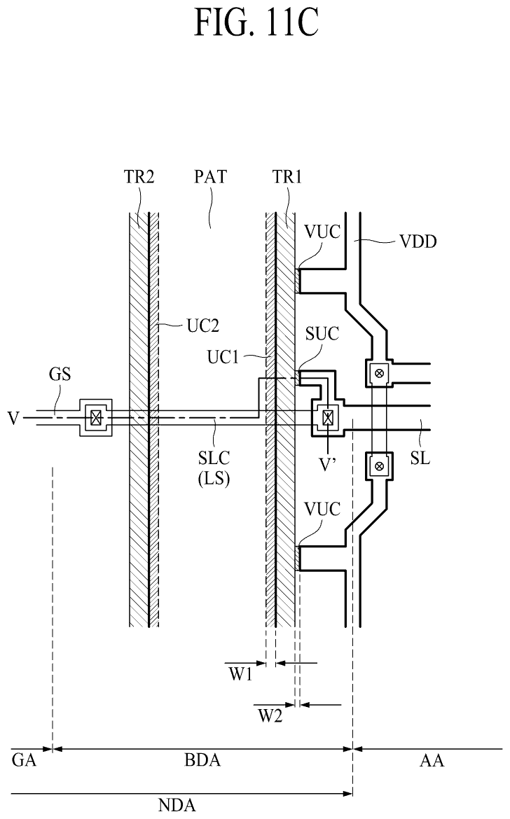

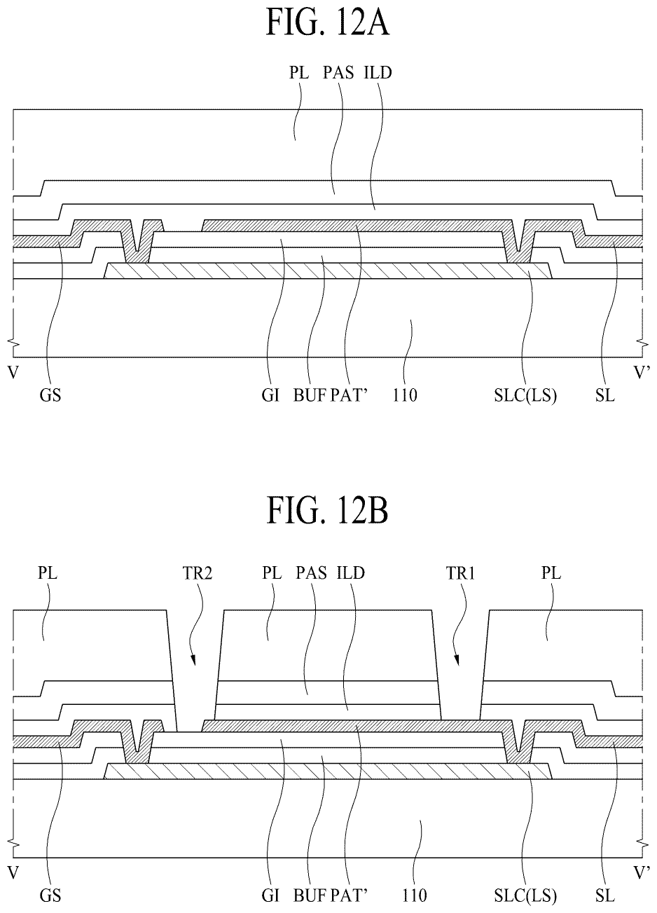

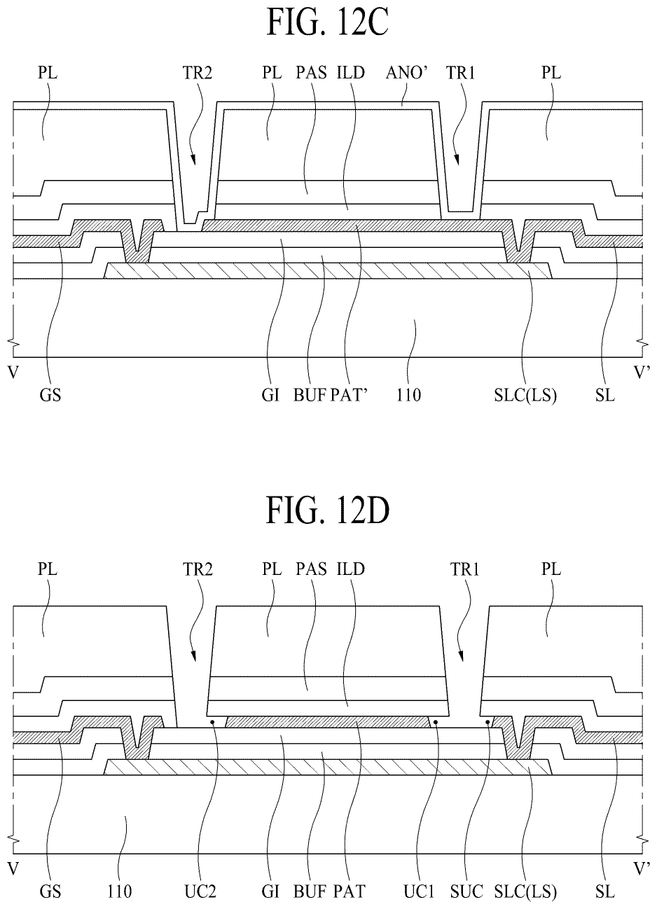

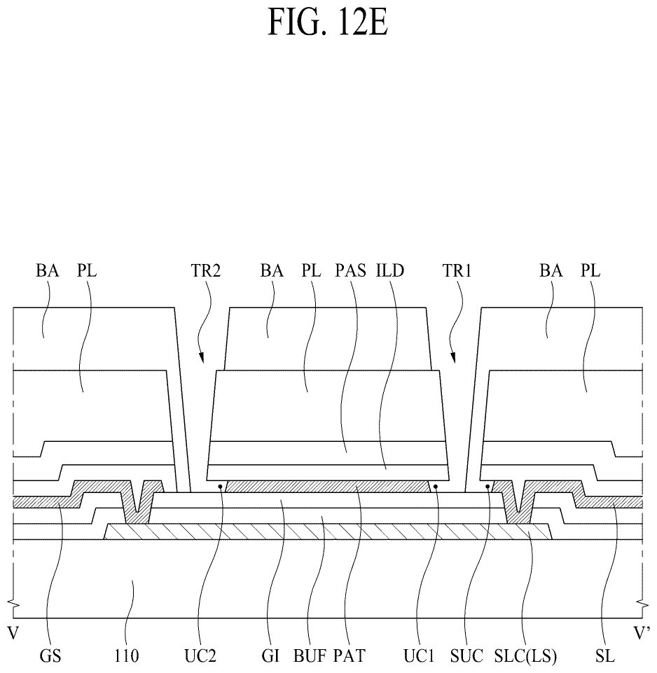

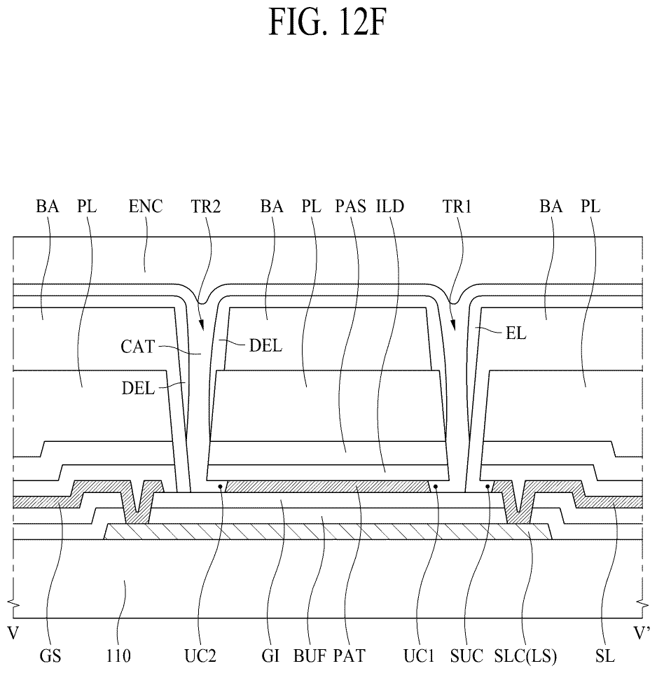

Hereinafter, referring to FIGS. 11A to 11C and FIGS. 12A to 12F, a light emitting display device according to a fifth example aspect of the present disclosure will be explained. FIGS. 11A to 11C are enlarged plane views illustrating a method for manufacturing a light emitting display device according to the fifth example aspect of the present disclosure. FIGS. 12A to 12F are enlarged cross-sectional views, along the cutting line V-V′, illustrating a method for manufacturing the light emitting display device according to the fifth example aspect of the present disclosure.

In the fifth example aspect, the description will focus on the manufacturing process. The light emitting display device according to the fifth example aspect can have very similar structure with that of the light emitting display device according to the fourth example aspect. In particular, the elements disposed in the boundary area BDA including main features of the present disclosure can have the same or substantially the same structure. The difference is on that the driving current line VDD can be connected to the pattern electrode PAT running along Y-axis of the substrate 110 like the scan line SL. Further, a portion where the scan line SL and the driving current line VDD are connected to and then separated from the pattern electrode PAT can have the characteristics of having the same width as the width of the line.

Referring to FIGS. 11A and 12A, a scan link line SLC can be disposed on the substrate 110. The scan link line SLC can be disposed in the boundary area BDA. The scan link line SLC can be made of the same material and disposed on the same layer with the light shielding layer LS. A buffer layer BUF and a gate insulating layer GI can be sequentially deposited on the scan link line SLC. The buffer layer BUF and the gate insulating layer GI can be collectively referred to as an ‘insulating layer’. The gate signal line GS and the scan line SL can be disposed on the gate insulating layer GI. The scan line SLC can extend from the display area AA to the boundary area BDA. In particular, the scan line SL can be connected to the pattern electrode PAT′ overlapped with the scan link line SLC (e.g., the middle portion of the scan link line SLC). Here, the pattern electrode PAT′ is in condition to be one body with the scan line SL, so the numeric symbol is referred to as PAT′. Although it is illustrated that a connection portion between the scan line SL and the pattern electrode PAT′ is spaced apart from the scan link line SLC in a plane view, embodiments are not limited thereto. As an example, the connection portion between the scan line SL and the pattern electrode PAT′ may at least partially or fully overlap the scan link line SLC in a plane view.

The gate signal line GS can be apart from the pattern electrode PAT′ with a predetermined distance. However, it is not limited thereto. The gate signal line GS can be connected to the pattern electrode PAT′. An intermediate insulating layer ILD and a passivation layer PAS can be sequentially stacked on the gate signal line GS, the pattern electrode PAT′ and the scan line SL. A planarization layer PL can be deposited on the passivation layer PAS.

Referring to FIG. 11B and FIG. 12B, by sequentially etching the planarization layer PL, the passivation layer PAS and the intermediate insulating layer ILD, a first trench TR1 and a second trench TR2 can be formed. The first trench TR1 can expose a portion where the scan line SL and the first side of the pattern electrode PAT′ are connected, and the second trench TR2 can expose a portion of the second side of the pattern electrode PAT′. Here, the portion where the driving current line VDD and the first side of the pattern electrode PAT′ are connected can be exposed by the first trench TR1. However, the gate signal line GS may not be exposed.

However, it is not limited thereto. When the gate signal line GS is connected to the pattern electrode PAT′, the portion where the gate signal line GS and the second side of the pattern electrode PAT′ are connected can be exposed by the second trench TR2.

Referring to FIG. 12C, after forming the first trench TR1 and the second trench TR2, the anode electrode layer ANO′ can be deposited. Here, the anode electrode layer ANO′ is in a state in which a metal material layer to be used as an anode electrode is applied to the upper surface of the substrate 110, before forming the anode electrode.

Referring to FIG. 11C and FIG. 12D, by patterning the anode electrode layer ANO′, an anode electrode can be formed. The anode electrode can be disposed at one pixel, with one-to-one correspondence, in the display area AA. In the boundary area BDA, the anode electrode layer ANO′ can be removed, and then the first side and the second side of the exposed pattern electrode PAT′ exposed by the first trench TR1 and the second trench TR2 can be etched. As a result, a pattern electrode PAT separated from the scan line SL can be formed. Further, by proceeding the etching process, the first under-cut UC1 and the second under-cut UC2 can be formed, wherein the first and second sides of the pattern electrode PAT are eroded into the lower part of the intermediate insulating layer ILD. At this time, at the end of the scan line SL, a scan line under-cut SUC can be formed by the over-etching process, wherein the end of the scan line SL is eroded into the lower part of the intermediate insulating layer ILD.

The driving current line VDD can also be separated from the pattern electrode PAT. Further, the end of the driving current line VDD can be over-etched. As a result, a driving line under-cut VUC can be formed, wherein the end of the driving current line VDD is eroded into the lower part of the intermediate insulating layer ILD.

The first under-cut UC1 and the second under-cut UC2 of the pattern electrode PAT are exposed along the first side and the second side, respectively, so the under-cuts can be formed as the over-etching speed progresses rapidly. For example, the first under-cut UC1 and the second under-cut UC2 can have a first erosion width W1. Meanwhile, in the case of the scan line under-cut SUC and the drive line under-cut VUC, the surface exposed by the first trench TR1 is very narrow, so over-etching can proceed at a relatively slow rate. For example, the scan line under-cut SUC and the driving line under-cut VUC can have a second erosion width W2 narrower than the first erosion width W1. For example, the second erosion width W2 can be 20% to 50% of the first erosion width W1. Embodiments are not limited thereto. As an example, over-etching may proceed at the same or substantially the same rate for the first under-cut UC1, the second under-cut UC2, the scan line under-cut SUC and the drive line under-cut VUC. As an example, the second erosion width W2 may be equal to or even greater than the first erosion width W1.

Referring to FIG. 11C and FIG. 12E, a bank BA can be formed on the substrate 110 having the first under-cut UC1, the second under-cut UC2, the scan line under-cut SUC and the driving line under-cut VUC. The bank BA can expose some edge portions of the planarization layer PL covering the pattern electrode PAT to expose the first side of the pattern electrode PAT in the first trench TR1. Further, the bank BA can expose some edge portions of the planarization layer PL covering the pattern electrode PAT to expose the second side of the pattern electrode PAT in the second trench TR2. For another example, the bank BA may not be formed over the pattern electrode PAT. On the contrary, the bank BA can cover the area where the scan line under-cut SUC and the driving line under-cut VUC are formed. Further, the bank BA can cover the side wall of the planarization layer PL covering the end of the gate signal line GS in the second trench TR2.

Referring to FIG. 12F, an emission layer EL can be deposited on the substrate 110 having the first trench TR1, the second trench TR2, the first under-cut UC1 and the second under-cut UC2. The emission layer EL can be deposited from the display area AA to the non-display area NDA. However, the connectivity of the emission layer EL can be disconnected by the first trench TR1 and the first under-cut UC1, and the second trench TR2 and the second under-cut UC2. As a result, the dummy emission layer DEL can be deposited in the gate driving area GA where the gate signal line GS is disposed, and the dummy emission layer DEL can be disposed in the boundary area BDA where the pattern electrode PAT is formed. The dummy emission layer DEL disposed in the gate driving area GA can be separated from the dummy emission layer DEL disposed in the boundary area BDA.

A cathode electrode CAT can be deposited on the substrate 110 having the emission layer EL and the dummy emission layer DEL. The cathode electrode CAT can have a one-body metal layer extended from the display area AA to the non-display area AA as covering the first trench TR1, the first under-cut UC1, the second trench TR2 and the second under-cut UC2.

An encapsulation layer ENC can be disposed on the cathode electrode CAT. The encapsulation layer ENC can have different elements and structure for the top emission type and the bottom emission type. However, what is common features is that the encapsulation layer ENC can cover the first trench TR1 and the second trench TR2 on the cathode electrode CAT, and extend from the display area AA and the non-display area NDA.

In the light emitting display device according to the fifth example aspect, during the manufacturing process, the pattern electrode PAT′ can be connected to the scan line SL and the driving current line VDD, so the pattern electrode PAT′ can be used as a shorting-bar for extracting the static electricity. Further, during forming the anode electrode, the pattern electrode PAT can be separated from the scan line SL and the driving current line VDD. At this time, the scan line SL can be separated from the driving current line VDD. After that, the pattern electrode PAT can be connected to the cathode electrode CAT, so the pattern electrode PAT can be used for a ground line.

### Sixth Example Aspect

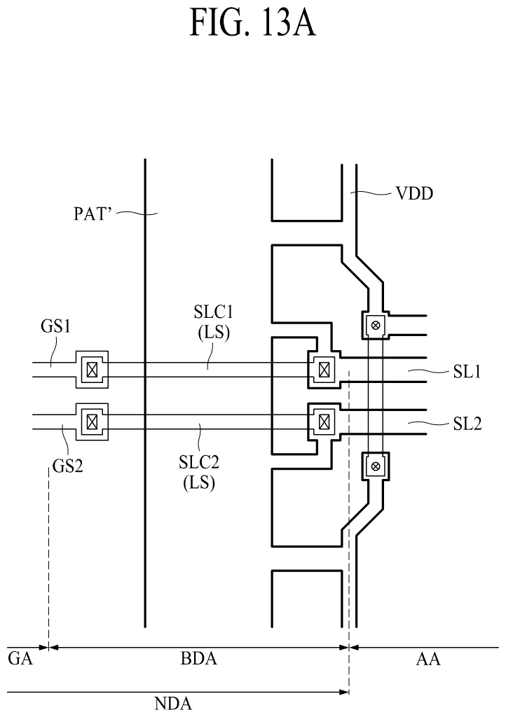

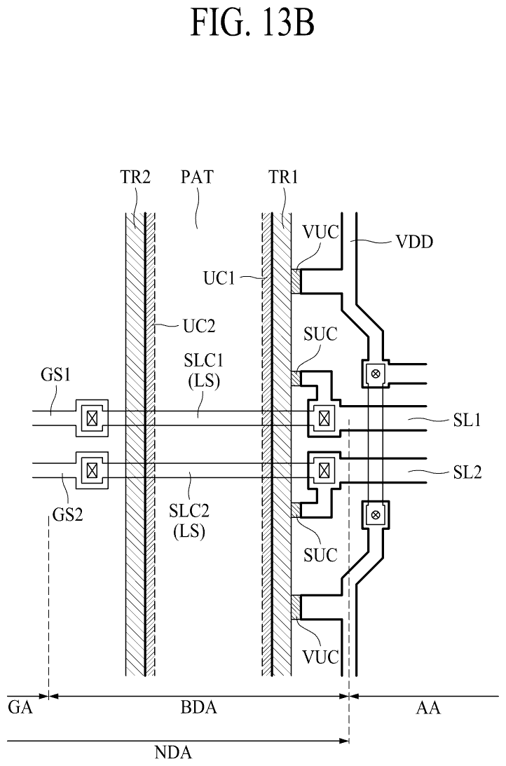

Hereinafter, referring to FIG. 13A and FIG. 13B, a light emitting display device according to a sixth example aspect will be explained. FIGS. 13A and 13B are enlarged plane views illustrating a method for manufacturing a light emitting display device according to the sixth example aspect of the present disclosure.

The light emitting display device according to the sixth example aspect of the present disclosure can have very similar structure to that of the second example aspect. The sixth example aspect can suggest a structure in which the scan line includes a first scan line SL1 and a second scan line SL2.

Referring to FIG. 13A, a first scan line SL1 and a second scan line SL2 can be disposed in the display area AA. A first gate signal line GS1 and a second gate signal line GS2 can be disposed in the gate driving area GA. A first scan link line SLC1 and a second scan link line SLC2 can be disposed in the boundary area BDA. The first scan link line SLC1 can link the first gate signal line GS1 to the first scan line SL1. The second scan link line SLC2 can link the second gate signal line GS2 to the second scan line SL2. The first scan line SL1 and the second scan line SL2 can be supplied with independent signals, respectively. As an example, the first scan line SL1 and the second scan line SL2 may be supplied with different signals, respectively. However, it is not limited thereto. The first scan line SL1 and the second scan line SL2 can be supplied with the same signal.

The pattern electrode PAT′ can be disposed in the boundary area BDA. During the manufacturing process, as shown in FIG. 13A, the first scan line SL1 and the second scan line SL2 can be connected to the pattern electrode PAT′. Further, the driving current line VDD can be connected to the pattern electrode PAT′. With this structure, the static electricity occurring during the manufacturing process can be extracted outside, so the first scan line SL1, the second scan line SL2 and the driving current line VDD can be reduced or prevented from being damaged due to the insulation breakdown by the static electricity.

Referring to FIG. 13B, by patterning the insulating layer covering the pattern electrode PAT′, the first scan line SL1, the second scan line SL2 and the driving current line VDD, the first trench TR1 and the second trench TR2 can be formed, and the first scan line SL1, the second scan line SL2 and the driving current line VDD can be separated from the pattern electrode PAT′. After that, by further proceeding the over-etching process, the first under-cut UC1 and the second under-cut UC2 can be formed. At this time, a scan under-cut SUC can be formed at the end of the first scan line SL1 and the second scan line SL2. Further, a driving line under-cut VUC can be formed at the end of the driving current line VDD.

Like the fifth example aspect, the first under-cut UC1 and the second under-cut UC2 can have different erosion width from the scan line under-cut SUC and the driving line under-cut VUC. However, it is not limited thereto. The first under-cut UC1, the second under-cut UC2, the scan line under-cut SUC and the driving line under-cut VUS can have the same erosion width. The erosion width can be same or different.

In the light emitting display device according to the sixth example aspect, during the manufacturing process, the pattern electrode PAT′ can be connected to the first scan line SL1, the second scan line SL2 and the driving current line VDD, so the pattern electrode PAT′ can be used as a shorting-bar for extracting the static electricity. Further, during forming the anode electrode, the pattern electrode PAT can be separated from the first scan line SL1, the second scan line SL2 and the driving current line VDD. At this time, the first scan line SL1, the second scan line SL2 and the driving current line VDD can be separated from each other. After that, the pattern electrode PAT can be connected to the cathode electrode CAT, so the pattern electrode PAT can be used for a ground line.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment can be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the disclosure and the claims, but should be construed to include all possible embodiments along with the full scope of equivalents to which such claims are entitled. Accordingly, the claims are not limited by this disclosure.

What is claimed is:

1. A light emitting display device comprising:
a display area disposed in a middle portion of a substrate;
a non-display area disposed adjacent to the display area on the substrate;
a boundary area disposed in the non-display area near the display area;
a pattern electrode disposed in the boundary area and surrounding the display area;
a trench disposed along the pattern electrode; and
an under-cut disposed at least one side of the pattern electrode along the trench.

2. The light emitting display device according to claim 1, further comprising:
an insulating layer deposited on the pattern electrode,
wherein the trench is an area where the insulating layer is removed along a first side of the pattern electrode, and
wherein the under-cut is a space formed by the first side of the pattern electrode being eroded into a lower inside of the insulating layer.

3. The light emitting display device according to claim 2, further comprising:
an emission layer on the insulating layer; and
a cathode electrode on the emission layer,
wherein the emission layer is disconnected by the trench and the under-cut between the display area and the non-display area, and
wherein the cathode electrode contacts the pattern electrode exposed by the under-cut, and fills inside of the trench.

4. The light emitting display device according to claim 3, further comprising:
an encapsulation layer on the cathode electrode,
wherein the encapsulation layer covers the trench.

5. The light emitting display device according to claim 1, wherein the pattern electrode includes:
a first side facing the display area; and
a second side apart from the first side to the non-display area,
wherein the trench includes:
a first trench along the first side of the pattern electrode; and
a second trench along the second side of the pattern electrode, and
wherein the under-cut includes:
a first under-cut along the first side of the pattern electrode; and
a second under-cut along the second side of the pattern electrode.

6. The light emitting display device according to claim 5, further comprising:
an insulating layer on the pattern electrode;
an emission layer on the insulating layer; and
a cathode electrode on the emission layer,
wherein the emission layer is disconnected at the first trench and the second trench, and
wherein the cathode electrode contacts the first side of the first pattern electrode exposed by the first under-cut, contacts the second side of the first pattern electrode exposed by the second under-cut, and fills inside of the trench.

7. The light emitting display device according to claim 1, wherein the pattern electrode includes:
a first pattern electrode near the display area; and
a second pattern electrode apart from the first pattern electrode to the non-display area,
wherein the trench includes:
a first trench disposed between the first pattern electrode and the display area;
a second trench disposed between the second pattern electrode and the non-display area; and
a third trench disposed between the first pattern electrode and the second pattern electrode, and
wherein the under-cut includes:
a first under-cut disposed at the first pattern electrode along the first trench;
a second under-cut disposed at the second pattern electrode along the second trench;
a third under-cut disposed at the first pattern electrode in the third trench; and
a fourth under-cut disposed at the second pattern electrode in the third trench.

8. The light emitting display device according to claim 7, further comprising:
an insulating layer disposed on the first pattern electrode and the second pattern electrode;
an emission layer on the insulating layer; and
a cathode electrode on the emission layer,
wherein the emission layer is disconnected at the first trench, the second trench and the third trench, and
wherein the cathode electrode contacts the first pattern electrode exposed by the first under-cut and the third under-cut, contacts the second pattern electrode exposed by the second under-cut and the fourth under-cut, and fills insides of the first trench, the second trench and the third trench.

9. The light emitting display device according to claim 1, further comprising:
a scan line disposed in the display area;
a gate signal line disposed at out of the boundary area in the non-display area; and
a link line overlapped with the pattern electrode in the boundary area, and connecting the scan line to the gate signal line.

10. The light emitting display device according to claim 9, wherein the trench is disposed between the pattern electrode and the scan line, and
wherein the light emitting display further comprises:
a scan line under-cut disposed at one side of the scan line facing the pattern electrode.

11. The light emitting display device according to claim 1, further comprising:
a gate driving area near to the boundary area and far from the display area;
a scan line disposed in the non-display area;
a gate signal line disposed in the gate driving area; and
a link line overlapped with the pattern electrode in the boundary area, and connecting the scan line to the gate signal line.

12. The light emitting display device according to claim 11, further comprising:
an insulating layer on the pattern electrode;
an emission layer on the insulating layer; and
a cathode electrode on the emission layer,
wherein the trench includes a first trench formed by removing the insulating layer between the pattern electrode and the scan line,
wherein the under-cut includes a first under-cut formed by one end of the pattern electrode being eroded under the insulating layer in the first trench,
wherein the emission layer is disconnected by the first trench and the first under-cut, and
wherein the cathode electrode contacts the pattern electrode exposed by the first under-cut, and fills inside of the first trench.

13. The light emitting display device according to claim 12, further comprising:
a scan line under-cut formed by one end of the scan line being eroded under the insulating layer in the first trench; and
a bank disposed on the insulating layer, and covering the scan line under-cut.

14. The light emitting display device according to claim 11, further comprising:
an insulating layer covering the pattern electrode;
an emission layer on the insulating layer; and
a cathode electrode on the emission layer,
wherein the trench includes a second trench formed by removing the insulating layer between the pattern electrode and the gate signal line,
wherein the under-cut includes a second under-cut formed by another end of the pattern electrode being eroded under the insulating layer in the second trench,
wherein the emission layer is disconnected by the second trench and the second under-cut, and
wherein the cathode electrode contacts the pattern electrode exposed from the second under-cut, and fills inside of the second trench.

15. The light emitting display device according to claim 14, further comprising:
a gate signal line under-cut formed by an end of the gate signal line being eroded under the insulating layer in the second trench; and
a bank disposed on the insulating layer, and covering the gate signal line under-cut.
